(19) United States
(12) Patent Application Publication
(10) Pub. No.: US 2026/0297391 A1
(43) Pub. Date: Oct. 1, 2026

(54) ADHESIVE FILM, ADHESIVE FILM WITH METAL LAYER, WIRING FORMATION MEMBER, FORMATION METHOD FOR WIRING LAYER, AND WIRED MEMBER

(71) Applicant: Resonac Corporation, Minato-ku, Tokyo (JP)

(72) Inventors: Masashi OHKOSHI, Tokyo (JP); Seiichi KUSAKA, Tokyo (JP); Yuka ITOH, Tokyo (JP)

(21) Appl. No.: 19/477,781

(22) PCT Filed: Aug. 2, 2024
(86) PCT No.: PCT/JP2024/027776

§ 371 Date: Oct. 23, 2025

(30) Foreign Application Priority Data
Aug. 8, 2023 (JP) 2023-129157

(51) Int. Cl. C09J 7/28; C09J 11/04; H05K 1/02; H05K 1/03; H05K 1/09; H05K 3/06; H05K 3/46

(52) U.S. Cl. CPC C09J 7/28; C09J 11/04; H05K 1/0298; H05K 1/036; H05K 1/095; H05K 3/06; H05K 3/4655; C09J 2203/326; C09J 2301/312; C09J 2301/408; C09J 2400/163; H05K 2203/1189

(57) ABSTRACT

A metal layer-attached adhesive film includes a metal layer and an adhesive layer disposed on the metal layer, wherein the adhesive layer includes conductive particles and a thermosetting resin composition, and a cured product of the adhesive layer has a thermal expansion coefficient of 1.5% to 3% when heated from 40° C. to 260° C.

### TECHNICAL FIELD

The present disclosure relates to an adhesive film, a metal layer-attached adhesive film, a member for wiring formation, a method for forming a wiring layer, and a wiring-formed member.

### BACKGROUND ART

Patent Literature 1 discloses a method for producing a printed wiring board having an embedded electronic component such as an IC chip.

### CITATION LIST

### Patent Literature

Patent Literature 1: Japanese Unexamined Patent Publication No. 2012-191204

### SUMMARY OF INVENTION

### Technical Problem

In a conventional method for manufacturing a component-embedded substrate, as shown in (a) and (b) of FIG. 8, insulating resin layers 102 and 103 are formed on both sides in the lamination direction of an electronic component 101 provided with an electrode 101a. Thereafter, as shown in (c) and (d) of FIG. 8, via electrodes 104 and 105 reaching each electrode 101a of the electronic component 101 are formed in each of the insulating layers 102 and 103 by performing hole drilling with a laser, formation of a plating layer, formation of electrodes by etching, and the like. Then, as shown in (a) to (c) of FIG. 9, a component-embedded substrate 110 is formed by further repeating the formation of insulating resin layers 106 and 107, formation of a via electrode 108 by hole drilling with a laser and formation of a plating layer, formation of an electrode by etching, and the like. However, in such a method for manufacturing a component-embedded substrate, many treatments are carried out to form one conductive layer (via electrode), and in order to form a plurality of conductive layers, it is necessary to repeat these treatments, making the manufacturing process very complicated.

Thus, an adhesive having a metal layer such as a metal foil laminated thereon and having conductive particles has been examined as a member for wiring formation. With such a member for wiring formation, it can be expected that a wiring layer connected to a wiring is conveniently formed on a base material on which the wiring is formed, by going through a step of disposing a member for wiring formation on a surface of the base material on which a wiring is formed, such that the adhesive layer faces the base material; a step of heating and pressure-bonding the member for wiring formation against the base material; and a step of performing a patterning treatment on the metal layer.

Meanwhile, the above-mentioned component-embedded substrate used in a semiconductor package or the like may be subjected to a load caused by thermal expansion of members in a high-temperature environment such as a reflow treatment step. At this time, when an excessive load is generated at a connecting part formed as described above, an increase in the connection resistance attributable to conduction failure, swelling, peeling, and the like becomes a problem. On the other hand, from the viewpoints of productivity and handling such as roll-to-roll application, the member for wiring formation is required to have crack resistance that does not allow crack generation during winding. Furthermore, the crack resistance during winding is also necessary when the member is slitted to a predetermined width. However, there is a tendency that an adhesive layer made of a resin designed to be able to form a connecting part with enhanced heat resistance is less likely to provide crack resistance.

Thus, it is an object of the present disclosure to provide an adhesive film that has sufficient crack resistance, can connect between wirings that face each other, with sufficient conductivity, and can also form a connecting part having excellent connectivity even under high temperature conditions; a metal layer-attached adhesive film and a member for wiring formation, which have sufficient crack resistance, can simplify a process of forming a wiring layer that connects between wirings, and can also form a wiring layer having excellent connectivity even under high temperature conditions; as well as a method for forming a wiring layer and a wiring-formed member, which use the metal layer-attached adhesive film and the member for wiring formation.

### Solution to Problem

In order to solve the above-described problems, the present disclosure provides the following adhesive film, metal layer-attached adhesive film, member for wiring formation, method for forming a wiring layer, and wiring-formed member.
[1] An adhesive film comprising conductive particles and a thermosetting resin composition, wherein a cured product of the adhesive film has a thermal expansion coefficient of 1.5% to 3% when heated from 40° C. to 260° C.
[2] The adhesive film according to [1], wherein the adhesive film has a reaction ratio of 90% or less when heated at 180° C. for 5 minutes.
[3] The adhesive film according to [1] or [2], wherein the conductive particles include copper particles.
[4] A metal layer-attached adhesive film including a metal layer and an adhesive layer disposed on the metal layer, wherein the adhesive layer comprises conductive particles and a thermosetting resin composition, and a cured product of the adhesive layer has a thermal expansion coefficient of 1.5% to 3% when heated from 40° C. to 260° C.
[5] The metal layer-attached adhesive film according to [4], wherein the adhesive layer has a reaction ratio of 90% or less when heated at 180° C. for 5 minutes.
[6] The metal layer-attached adhesive film according to [4] or [5], wherein the conductive particles include copper particles.
[7] The metal layer-attached adhesive film according to any one of [4] to [6], wherein the metal layer-attached adhesive film is used for forming a wiring.
[8] A member for wiring formation having an adhesive layer and a metal layer provided as separate entities, the adhesive layer being adherable to the metal layer at the time of use, wherein the adhesive layer comprises conductive particles and a thermosetting resin composition, and a cured product of the adhesive layer has a thermal expansion coefficient of 1.5% to 3% when heated from 40° C. to 260° C.
[9] The member for wiring formation according to [8], wherein the adhesive layer has a reaction ratio of 90% or less when heated at 180° C. for 5 minutes.
[10] The member for wiring formation according to [8] or [9], wherein the conductive particles include copper particles.
[11] A method for forming a wiring layer, the method including: a step of providing the metal layer-attached adhesive film according to any one of [4] to [6]; a step of providing a base material on which a wiring is formed; a step of disposing the metal layer-attached adhesive film to a surface of the base material on which a wiring is formed so that the metal layer-attached adhesive film covers the wiring, such that the adhesive layer faces the base material; a step of heating and pressure-bonding the metal layer-attached adhesive film to the base material; and a step of performing a patterning treatment on the metal layer.
[12] A method for forming a wiring layer, the method including: a step of providing the member for wiring formation according to any one of [8] to [10]; a step of providing a base material on which a wiring is formed; a step of disposing the member for wiring formation on the surface of the base material on which a wiring is formed so that the member for wiring formation covers the wiring, such that the adhesive layer faces the base material; a step of heating and pressure-bonding the member for wiring formation to the base material; and a step of performing a patterning treatment on the metal layer.
[13] A wiring-formed member including: a base material having a wiring; and a cured product of the adhesive layer of the metal layer-attached adhesive film according to any one of [4] to [6] disposed on the base material to cover the wiring, wherein the wiring is electrically connected to the metal layer of the metal layer-attached adhesive film or another wiring formed from the metal layer.
[14] A wiring-formed member including: a base material having a wiring; and a cured product of the adhesive layer of the member for wiring formation according to any one of [8] to [10] disposed on the base material to cover the wiring, wherein the wiring is electrically connected to the metal layer of the member for wiring formation or another wiring formed from the metal layer.

### Advantageous Effects of Invention

According to the present disclosure, there can be provided an adhesive film that has sufficient crack resistance, can connect between wirings that face each other, with sufficient conductivity, and can also form a connecting part having excellent connectivity even under high temperature conditions; a metal layer-attached adhesive film and a member for wiring formation, which have sufficient crack resistance, can simplify a process of forming a wiring layer that connects between wirings, and can also form a wiring layer having excellent connectivity even under high temperature conditions; as well as a method for forming a wiring layer and a wiring-formed member, which use the metal layer-attached adhesive film and the member for wiring formation.

### BRIEF DESCRIPTION OF DRAWINGS

FIG. 1 is a cross-sectional view illustrating a member for wiring formation according to an embodiment of the present disclosure.

FIGS. 2 (a) to (d) of FIG. 2 are drawings for sequentially describing a method for forming a wiring layer using the member for wiring formation shown in FIG. 1.

FIGS. 3 (a) to (c) of FIG. 3 are cross-sectional views illustrating members for wiring formation according to other embodiments of the present disclosure and the state in which those members for wiring formation are pressure-bonded.

FIG. 4 is a cross-sectional view illustrating a member for wiring formation according to another embodiment of the present disclosure.

FIGS. 5 (a) to (d) of FIG. 5 are drawings for sequentially describing a method for forming a wiring layer using the member for wiring formation shown in FIG. 4.

FIGS. 6 (a) and (b) of FIG. 6 are cross-sectional views for describing an example of a case in which a wiring layer is formed using the member for wiring formation shown in FIG. 4.

FIGS. 7 (a) and (b) of FIG. 7 are cross-sectional views for describing another example of the case in which a wiring layer is formed using the member for wiring formation shown in FIG. 4.

FIGS. 8 (a) to (d) of FIG. 8 are cross-sectional views for sequentially describing a conventional method for manufacturing a component-embedded substrate.

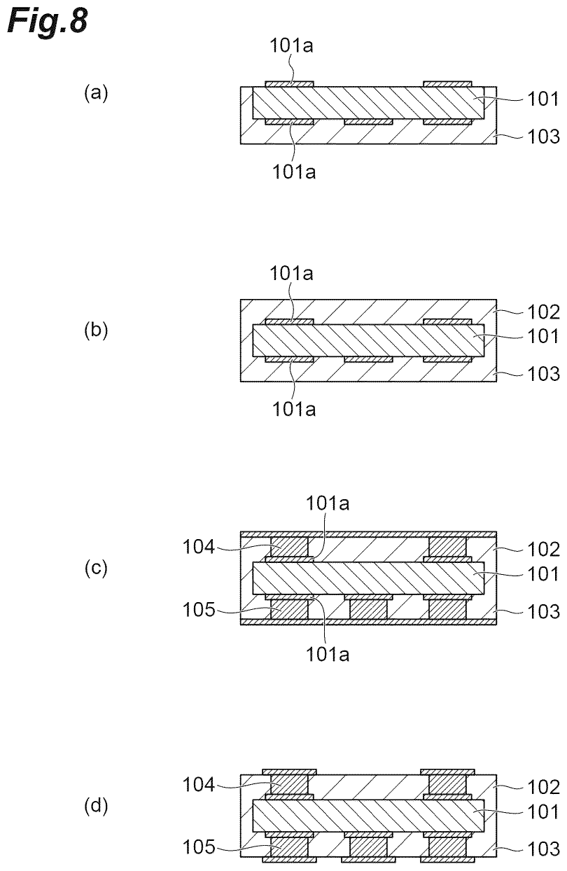

FIGS. 9 (a) to (c) of FIG. 9 are cross-sectional views for sequentially describing a conventional method for manufacturing a component-embedded substrate and show steps subsequent to FIG. 8.

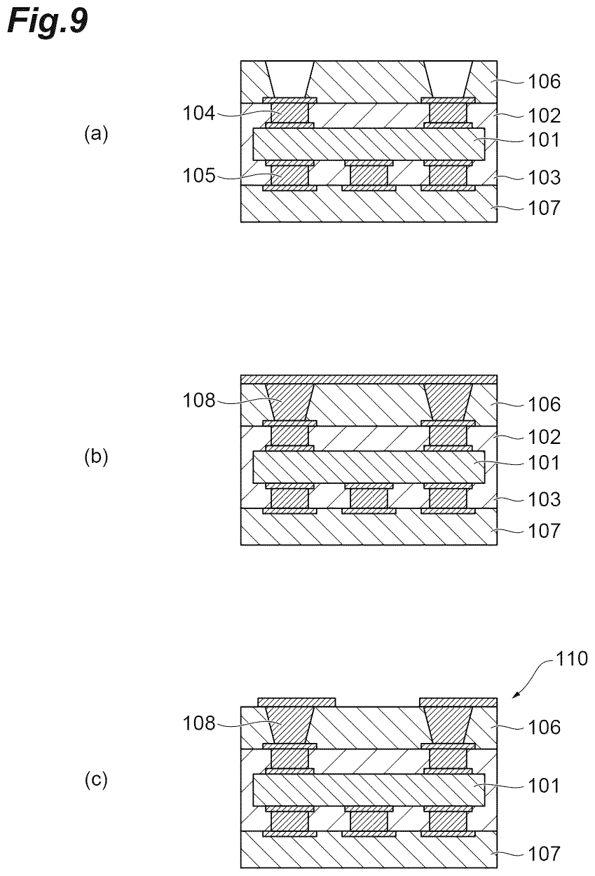

### DESCRIPTION OF EMBODIMENTS

Hereinafter, a metal layer-attached adhesive film and a member for wiring formation according to an embodiment of the present disclosure, a method for forming a wiring layer using the metal layer-attached adhesive film and the member for wiring formation, as well as an adhesive film will be described with reference to the drawings. In the following description, the same reference numeral will be assigned to the same or equivalent parts, and any duplicate description will not be repeated. Furthermore, it should be noted that unless particularly stated otherwise, the positional relations such as up, down, right, and left are based on the positional relations shown in the drawings. The dimensional ratios of the drawings are not limited to the ratios shown in the drawings.

A numerical value range shown using the term “to” in the present specification includes the numerical values described before and after the term “to” as the minimum value and the maximum value, respectively. Furthermore, in a numerical value range described stepwise in the present specification, the upper limit value or lower limit value described in one numerical value range may be replaced with the upper limit value or lower limit value of another numerical value range described stepwise. Furthermore, in a numerical value range described in the present specification, the upper limit value or lower limit value of the numerical value range may be replaced with a value shown in the Examples.

The metal layer-attached adhesive film of the present embodiment includes a metal layer and an adhesive layer disposed on the metal layer, the adhesive layer contains copper particles and a thermosetting resin composition, and a cured product of the adhesive layer has a thermal expansion coefficient of 1.5% to 3% when heated from 40° C. to 260° C. The metal layer-attached adhesive film of the present embodiment can be used to form a wiring. In other words, the metal layer-attached adhesive film of the present embodiment may be a member for wiring formation. Hereinafter, the details of the metal layer-attached adhesive film of the present embodiment will be described by taking a case in which the metal layer-attached adhesive film is used as a member for wiring formation, as an example.

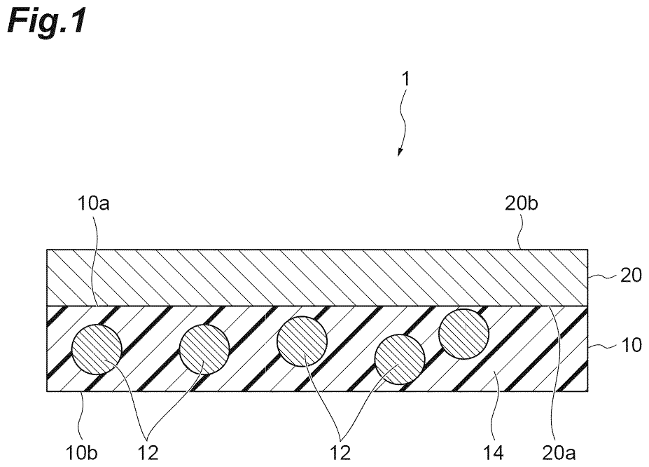

FIG. 1 is a cross-sectional view showing a member for wiring formation according to an embodiment of the present disclosure. As shown in FIG. 1, the member for wiring formation 1 is configured to include an adhesive layer 10 and a metal layer 20. The member for wiring formation 1 is not limited to these; however, for example, the member for wiring formation 1 is a member that can be used when producing a rewiring layer, a buildup multilayer wiring board, a component-embedded substrate, and the like. Furthermore, the member for wiring formation 1 may be used in an EMI shield and the like.

The adhesive layer 10 contains conductive particles 12 and an insulating adhesive component 14 in which the conductive particles 12 are dispersed. The adhesive component 14 in the adhesive layer 10 is defined as a solid component other than conductive particles such as the conductive particles 12. The adhesive layer 10 may be in a B-stage state, that is, a semi-cured state, before a wiring layer is formed using the member for wiring formation 1.

### [Configuration of Conductive Particle]

The conductive particles 12 are substantially spherical particles having electroconductivity and consist of metal particles made of a metal such as Au, Ag, Ni, Cu, or solder, conductive carbon particles made of conductive carbon, or the like. The conductive particles 12 may be coated conductive particles each having: a core containing non-conductive glass, ceramic, plastic (polystyrene or the like), or the like; and a coating layer that contains the above-described metal or conductive carbon and coats the core. Among these, the conductive particles 12 may be metal particles formed from a thermofusible metal, or coated conductive particles each having: a core containing plastic; and a coating layer that contains a metal or conductive carbon and coats the core. From the viewpoint of making short-circuiting of circuits less likely to occur, the conductive particles 12 may be copper particles.

According to an embodiment, the conductive particles 12 each include a core made of polymer particles (plastic particles) such as polystyrene, and a metal layer that coats the core. The polymer particles may have the surface substantially entirely coated with a metal layer, or a portion of the surface of the polymer particles may be exposed without being coated with a metal layer, as long as the function as a connecting material is maintained. The polymer particles may be particles containing, for example, a polymer that includes at least one monomer selected from styrene and divinylbenzene as a monomer unit.

The metal layer may be formed from various metals such as Ni, Ni/Au, Ni/Pd, Cu, NiB, Ag, and Ru. The metal layer may be an alloy layer made of an alloy of Ni and Au, an alloy of Ni and Pd, or the like. The metal layer may be a multilayer structure composed of a plurality of metal layers. For example, the metal layer may be composed of a Ni layer and an Au layer. The metal layer may be produced by plating, vapor deposition, sputtering, soldering, or the like. The metal layer may be a thin film (for example, a thin film formed by plating, vapor deposition, sputtering, or the like).

The conductive particles 12 may have an insulating layer.

Specifically, for example, on the outer side of the coating layer in the conductive particles of the above-described embodiment having a core (for example, a polymer particle) and a coating layer such as a metal layer that coats the core, an insulating layer that further covers the coating layer may be provided. The insulating layer may be an outermost surface layer located on the outermost surface of the conductive particle. The insulating layer may be a layer formed from an insulating material such as silica or an acrylic resin.

From the viewpoint of having excellent dispersibility and conductivity, the average particle size Dp of the conductive particles 12 may be 1 μm or more, may be 2 μm or more, or may be 5 μm or more. From the viewpoint of having excellent dispersibility and conductivity, the average particle size Dp of the conductive particles may be 50 μm or less, may be 30 μm or less, or may be 20 μm or less. From the above-described viewpoint, the average particle size Dp of the conductive particles may be 1 to 50 μm, may be 5 to 30 μm, may be 5 to 20 μm, or may be 2 to 20 μm.

The maximum particle size of the conductive particles 12 may be smaller than the minimum interval between electrodes (shortest distance between adjacent electrodes) in the wiring pattern. From the viewpoint of having excellent dispersibility and conductivity, the maximum particle size of the conductive particles 12 may be 1 μm or more, may be 2 μm or more, or may be 5 μm or more. From the viewpoint of having excellent dispersibility and conductivity, the maximum particle size of the conductive particles 12 may be 50 μm or less, may be 30 μm or less, or may be 20 μm or less. From the above-described viewpoint, the maximum particle size of the conductive particles may be 1 to 50 μm, may be 2 to 30 μm, or may be 5 to 20 μm.

In the present specification, measurement of the particle sizes of any 300 particles (pcs) is performed by observation using a scanning electron microscope (SEM), the average value of the obtained particle sizes is defined as the average particle size Dp, and the largest value thus obtained is defined as the maximum particle size of the particles. In a case where the shape of the particles is not spherical, such as a case where the particles have protrusions, the particle size of a particle is defined as the diameter of a circle circumscribing the particle in an SEM image.

The content of the conductive particles 12 is determined in accordance with the degree of fineness of the electrodes to be connected. For example, the blending amount of the conductive particles 12 is not particularly limited, but may be 0.1% by volume or more, may be 0.2% by volume or more, may be 1% by volume or more, may be 1.5% by volume or more, may be 2% by volume or more, may be 5% by volume or more, or may be 10% by volume or more, based on the total volume of the adhesive component (components excluding the conductive particles in the adhesive composition). When the above-described blending amount is in these ranges, resistance unevenness and reduction of conductivity tend to be suppressed. The blending amount of the conductive particles 12 may be 30% by volume or less, may be 15% by volume or less, or may be 10% by volume or less, based on the total volume of the adhesive components (components excluding the conductive particles 12 in the adhesive composition). When the above-described blending amount is in these ranges, there is a tendency that short-circuiting of circuits is less likely to occur. The “% by volume” is determined based on the volume of each component before curing at 23° C., and the volume of each component can be converted from weight to volume by utilizing specific gravity. Furthermore, the component may be added to a measuring cylinder or the like, in which an appropriate solvent (water, alcohol, or the like) that thoroughly wets the component without dissolving or swelling the component, and the increased volume can be determined as the volume of the component.

From the viewpoint of reducing the connection resistance between wirings, the adhesive layer 10 may contain copper particles as the conductive particles 12. In this case, when the area of the wiring layer to be formed becomes large (for example, becoming 50 mm□ or more (2500 mm² or more), unevenness of springback of copper particles caused by pressure unevenness is likely to occur, and the connectivity under high temperature conditions is likely to decrease; however, when the thermal expansion coefficient of the cured product that will be described below is in a specific range, a wiring layer having excellent connectivity under high temperature conditions can be formed while attempting a decrease in the connection resistance.

Regarding the copper particles, particles containing one or more kinds of Cu and alloys of Cu and other metals can be used. Examples of the alloy of Cu and other metals contain silver, zinc, nickel, gold, lead, tin, aluminum, manganese, beryllium, tungsten, and iron. From the viewpoint of making the connection resistance between wirings small or from the viewpoint of reducing the manufacturing cost, the content of Cu in the copper particles may be 50% by mass or more, may be 70% by mass or more, or may be 100% by mass.

The shape of the copper particles may be a spherical shape, an approximately spherical shape, a flake shape, a pillar shape, a rod shape, a needle shape, a plate shape, or a fiber shape.

From the viewpoint of lowering the connection resistance value between wirings or from the viewpoint of achieving higher definition of wirings, the average particle size Dp of the copper particles may be 0.5 μm or more, may be 1 μm or more, or may be 3 μm or more. From the viewpoint of improving the insulation properties between adjacent wirings, the average particle size Dp of the conductive particles may be 300 μm or less, may be 100 μm or less, or may be 50 μm or less. From the above-described viewpoints, the average particle size Dp of the conductive particles may be 0.5 to 300 μm, may be 1 to 100 μm, or may be 3 to 50 μm.

The maximum particle size of the copper particles may be smaller than the minimum interval between electrodes (shortest distance between adjacent electrodes) in the wiring pattern. From the viewpoint of lowering the connection resistance value between wirings, the maximum particle size of the copper particles may be 0.5 μm or more, may be 1 μm or more, or may be 3 μm or more. From the viewpoint of improving the insulation properties between adjacent wirings, the maximum particle size of the conductive particles may be 300 μm or less, may be 100 μm or less, or may be 50 μm or less. From the above-described viewpoint, the maximum particle size of the conductive particles may be 0.5 to 300 μm, may be 1 to 100 μm, or may be 3 to 50 μm.

From the viewpoint of reducing the connection resistance, the content of the copper particles can be set to 6% by volume or less based on the total volume of the adhesive layer. When the content of the copper particles is 6% by volume or less, the copper particles can be sufficiently flattened, and as a result, the connecting area between the adhesive layer and the electrodes or wirings provided on the base material as well as the metal layer can be sufficiently secured. It is generally believed that as the content of the conductive particles increases, the connection resistance decreases; however, in the case of copper particles, when the content exceeds 6% by volume, it has been clearly found by the studies of the present inventors that it is difficult to flatten the copper particles, making it difficult to reduce the connection resistance, and this can be said to be unexpected. From the viewpoint of reducing the connection resistance, improving the insulation properties between adjacent wirings, and reducing the manufacturing cost, the content of the copper particles may be 0.1% to 6% by volume, or may be 0.5% to 3% by volume.

From the viewpoint of reducing the connection resistance, the conductive particles 12 may satisfy one or more of the following conditions. From the viewpoint that satisfactory connectivity between wirings is likely to be obtained, the adhesive layer 10 may contain copper particles that satisfy one or more of the following conditions.
(i) The amount of change when a pressure of 50 mN per particle is applied is 1 to 5 μm.
(ii) After a pressure of 50 mN per particle is applied, the amount of restoration when the pressure is released is 1 μm or less.
(iii) The restoration ratio determined by the expression: (amount of restoration when a pressure of 50 mN per particle is applied and then the pressure is released)×100/(amount of change when a pressure of 50 mN per particle is applied) is 1% to 25%, or 1% to 5%.

The above-described amount of change and amount of restoration mean values that are determined by a microcompression test using a probe and measured under the following conditions.
Measuring apparatus: “FISCHERSCOPE HM2000” (manufactured by Fischer Instruments K.K.)
Probe size (area): 100 μm×100 μm
Pressing time: Pressing for 50 seconds/returning for 50 seconds
Measurement temperature: 25° C.
Thrust force: 50 mN

### [Configuration of Adhesive Layer/Adhesive Component]

The adhesive component 14 constituting the adhesive layer 10 may be a thermosetting resin composition. The components included in the thermosetting resin composition include a thermosetting resin, a curing agent, and a curing accelerator.

A thermosetting resin is a resin that shows curability by heat. Examples of the thermosetting resin include an epoxy resin, a polyimide resin, a triazine resin such as a melamine resin, a phenol resin, and modification products of these resins. Among these, from the viewpoint of sufficiently suppressing the occurrence of bubbles or peeling during wiring formation, the thermosetting resin may be an epoxy resin.

From the viewpoint of sufficiently suppressing the occurrence of bubbles or peeling during wiring formation and making it difficult for resistance unevenness to occur, the adhesive component can contain an epoxy resin and a phenol resin as thermosetting components.

The epoxy resin may be a compound having two or more epoxy groups in the molecule, and examples thereof include a bisphenol A type epoxy resin, a bisphenol F type epoxy resin, a bisphenol S type epoxy resin, a biphenyl type epoxy resin, a biphenyl novolac type epoxy resin, a phenol novolac type epoxy resin, a cresol novolac type epoxy resin, a bisphenol A novolac type epoxy resin, a bisphenol F novolac type epoxy resin, a naphthalene type polyfunctional epoxy resin, a dicyclopentadiene type epoxy resin, an alicyclic epoxy resin, an aliphatic chain-shaped epoxy resin, a glycidyl ester type epoxy resin, an isocyanurate type epoxy resin, a hydantoin type epoxy resin, a glycidyl ether compound of a polyfunctional phenol, a glycidyl ether compound of a bifunctional alcohol, and hydrogenation products thereof. Among these, from the viewpoints of handleability and easy availability, a novolac type epoxy resin such as a biphenyl novolac type epoxy resin, a phenol novolac type epoxy resin, a cresol novolac type epoxy resin, a bisphenol A novolac type epoxy resin, or a bisphenol F novolac type epoxy resin may be used. Regarding the epoxy resin, one kind thereof may be used alone, or two or more kinds thereof may be used in combination.

From the viewpoint of ensuring adhesive strength and heat resistance, the adhesive component may contain a compound having three or more epoxy groups in one molecule as the epoxy resin.

From the viewpoint of ensuring adhesive strength and heat resistance, and satisfactory reactivity, the epoxy resin may have an epoxy equivalent of 100 to 1000 g/eq, may have an epoxy equivalent of 125 to 900 g/eq, or may have an epoxy equivalent of 150 to 800 g/eq. The epoxy equivalent is determined by a method standardized in the JIS standard (K7236:2001).

The content of the epoxy resin in the adhesive component may be 5% to 95% by mass, may be 10% to 90% by mass, may be 15% to 85% by mass, or may be 40% to 60% by mass, based on the total amount of the adhesive component (total amount of solid content other than the conductive particles in the adhesive layer 10).

The phenol resin functions as a curing agent for the epoxy resin. Examples of the phenol resin include novolac type phenol resins such as phenol novolac, cresol novolac, bisphenol A novolac, bisphenol F novolac, and catechol novolac; and phenol resins in which the aromatic rings of these phenol resins substituted with alkyl groups. Regarding the phenol resin, one kind thereof may be used alone, or two or more kinds thereof may be used in combination.

From the viewpoint of ensuring adhesive strength and heat resistance, the adhesive component may contain a compound having three or more phenol groups or cresol groups in one molecule as the phenol resin. As such a compound, from the viewpoint of handleability and easy availability, a phenol novolac type phenol resin, a cresol novolac type phenol resin, a bisphenol A novolac type phenol resin, a bisphenol F novolac type phenol resin, or the like may be used.

From the viewpoint of suppressing the occurrence of bubbles or peeling during wiring formation and making it difficult for resistance unevenness to occur, the hydroxyl group equivalent of the phenol resin may be 300 g/eq or less or may be 250 g/eq or less, and from the viewpoints of easy handleability and satisfactory reactivity, the hydroxyl group equivalent may be 50 g/eq or more or may be 100 g/eq or more.

The hydroxyl group equivalent of the phenol resin is determined by the following measurement method.

### <Method for Measuring Hydroxyl Group Equivalent>

In a round-bottom flask, 1 g of a sample is precisely weighed out, and 5 mL of an acetic anhydride and pyridine reagent solution is precisely weighed out. Next, the flask is fitted with an air cooler, and the flask is heated at 100° C. for 1 hour. After cooling the flask, 1 mL of water is added thereto, and the flask is heated again at 100° C. for 10 minutes. After cooling the flask again, the air cooler and the neck part of the flask are rinsed in with 5 mL of neutralized methanol, and 1 mL of phenolphthalein reagent is added thereto. The solution obtained in this way is titrated using a 0.1 mol/L potassium hydroxide-ethanol solution, and the hydroxyl group value is determined. From the obtained hydroxyl group value, the hydroxyl group equivalent (g/eq) converted into mass per 1 mol (1 eq) of hydroxyl groups is calculated.

The content of the phenol resin in the adhesive component can be set such that the number of hydroxyl groups of the phenol resin is 0.5 to 2 per one epoxy group of the epoxy resin.

The adhesive component containing an epoxy resin and a phenol resin may further contain a thermosetting resin other than an epoxy resin and may further contain a curing agent other than a phenol resin. As the thermosetting resin other than an epoxy resin, a polyimide resin, a triazine resin such as a melamine resin, and modification products of these resins can be used. Examples of the curing agent other than a phenol resin include amines, amides, acid anhydrides, acids, and imidazoles.

Furthermore, in the member for wiring formation of the present embodiment, from the viewpoint of sufficiently suppressing the occurrence of bubbles or peeling during wiring formation, the adhesive component can further contain a maleimide compound.

In this case, from the viewpoint of sufficiently suppressing the occurrence of bubbles or peeling during wiring formation, the adhesive component may contain an epoxy resin as a thermosetting resin. The content of the epoxy resin in the adhesive component at this time may be 5% to 95% by mass, may be 10% to 90% by mass, may be 15% to 85% by mass, or may be 15% to 40% by mass, based on the total amount of the adhesive component (total amount of solid content other than the conductive particles in the adhesive layer 10).

A maleimide compound is a compound having at least one N-substituted maleimide group in one molecular structure. The maleimide compound may include, for example, at least one selected from the group consisting of a polymaleimide compound (m1) having at least two N-substituted maleimide groups in one molecular structure (hereinafter, may be referred to as “component (m1)”) and derivatives thereof. Examples of the “derivatives thereof” include an addition reaction product of a polymaleimide compound (m1) and an amine compound such as a diamine compound that will be described below. Since maleimide compounds have low reactivity, when the adhesive component 14 contains these, it is expected that the curing reaction will proceed slowly. As the curing reaction proceeds slowly, a sufficient flow time can be ensured, and it is possible to sufficiently suppress the occurrence of bubbles or peeling during wiring formation.

Examples of the component (m1) include N,N′-ethylenebismaleimide, N,N′-hexamethylenebismaleimide, N,N′-(1,3-phenylene)bismaleimide, N,N′-[1,3-(2-N,N′-[1,3-(4-methylphenylene)]bismaleimide, methylphenylene)]bismaleimide, N,N′-(1,4-phenylene)bismaleimide, bis(4-maleimidophenyl) methane, bis(3-methyl-4-maleimidophenyl) methane, 3,3-dimethyl-5,5-diethyl-4,4-diphenylmethanebismaleimide, bis(4-maleimidophenyl) ether, bis(4-maleimidophenyl) sulfone, bis(4-maleimidophenyl) sulfide, bis(4-maleimidophenyl) ketone, bis(4-maleimidocyclohexyl) methane, 1,4-bis(4-maleimidophenyl)cyclohexane, 1,4-bis(maleimidomethyl)cyclohexane, 1,4-bis(maleimidomethyl)benzene, 1,3-bis(4-maleimidophenoxy)benzene, bis[4-(3-maleimidophenoxy)phenyl]methane, bis[4-(4-maleimidophenoxy)phenyl]methane, 1,1-bis[4-(3-maleimidophenoxy)phenyl]ethane, 1,1-bis[4-(4-maleimidophenoxy)phenyl]ethane, 1,2-bis[4-(3-maleimidophenoxy)phenyl]ethane, 1,2-bis[4-(4-maleimidophenoxy)phenyl]ethane, 2,2-bis[4-(3-maleimidophenoxy)phenyl]propane, 2,2-bis[4-(4-maleimidophenoxy)phenyl]propane, 2,2-bis[4-(3-maleimidophenoxy)phenyl]butane, 2,2-bis[4-(4-maleimidophenoxy)phenyl]butane, 2,2-bis[4-(3-maleimidophenoxy)phenyl]-1,1,1,3,3,3-hexafluoropropane, 2,2-bis[4-(4-maleimidophenoxy)phenyl]-1,1,1,3,3,3-hexafluoropropane, 4,4-bis(3-maleimidophenoxy) biphenyl, 4,4-bis(4-maleimidophenoxy) biphenyl, bis[4-(3-maleimidophenoxy)phenyl]ketone, bis[4,4-(4-maleimidophenoxy)phenyl]ketone, 2,2-bis(4-maleimidophenyl)disulfide, bis(4-maleimidophenyl)disulfide, bis[4-(3-maleimidophenoxy)phenyl]sulfide, bis[4-(4-maleimidophenoxy)phenyl]sulfide, bis[4-(3-maleimidophenoxy)phenyl]sulfoxide, bis[4-(4-maleimidophenoxy)phenyl]sulfoxide, bis[4-(3-maleimidophenoxy)phenyl]sulfone, bis[4-(4-maleimidophenoxy)phenyl]sulfone, bis[4-(3-maleimidophenoxy)phenyl]ether, bis[4-(4-maleimidophenoxy)phenyl]ether, 1,4-bis[4-(4-maleimidophenoxy)-α,α-dimethylbenzyl]benzene, 1,3-bis[4-(4-maleimidophenoxy)-α,α-dimethylbenzyl]benzene, 1,4-bis [4-(3-maleimidophenoxy)-α,α-dimethylbenzyl]benzene, 1,3-bis[4-(3-maleimidophenoxy)-α,α-dimethylbenzyl]benzene, 1,4-bis[4-(4-maleimidophenoxy)-3,5-dimethyl-α,α-dimethylbenzyl]benzene, 1,3-bis [4-(4-maleimidophenoxy)-3,5-dimethyl-α,α-dimethylbenzyl]benzene, 1,4-bis[4-(3-maleimidophenoxy)-3,5-dimethyl-α,α-dimethylbenzyl]benzene, 1,3-bis[4-(3-maleimidophenoxy)-3,5-dimethyl-α,α-dimethylbenzyl]benzene, and polyphenylmethane maleimide (for example, manufactured by Daiwa Fine Chemicals Co., Ltd., trade name: BMI-2300). Regarding the maleimide compound, one kind thereof may be used alone, or two or more kinds thereof may be used in combination.

Among these maleimide compounds, bis(4-maleimidophenyl) methane, bis(4-maleimidophenyl) sulfone, N,N′-(1,3-phenylene)bismaleimide, 2,2-bis(4-(4-maleimidophenoxy)phenyl) propane, or polyphenylmethane maleimide, all of which have high reaction ratios and can be made more heat-resistant, are preferred, and from the viewpoint of solubility in solvents, bis(4-maleimidophenyl) methane is particularly preferred.

From the viewpoints of solubility in organic solvents, compatibility, and adhesiveness to metal foil, the maleimide compound may include a derivative of the polymaleimide compound (m1). The derivative of the polymaleimide compound (m1) may include, for example, a modified polymaleimide compound (M) having a structural unit derived from a polymaleimide compound (m1) and a structural unit derived from an amine compound (m2) having an amino group (hereinafter, may be referred to as “component (m2)”). The modified polymaleimide compound (M) can also be considered as an addition reaction product of the component (m1) and the component (m2). The structural unit derived from the component (m1) and the structural unit derived from the component (m2) included in the modified polymaleimide compound (M) may each be composed of one kind or composed of a combination of two or more kinds thereof.

The modified polymaleimide compound (M) may be a compound including a structure represented by the following Formula (1), which is obtained by subjecting a maleimide group carried by the component (m1) and an amino group carried by the component (m2) to an addition reaction. In Formula (1), the symbol * represents a bonding position.

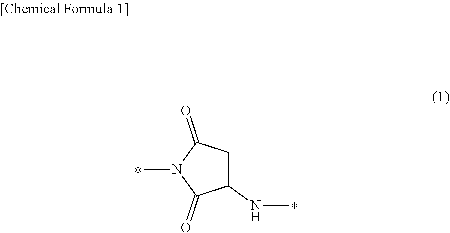

The component (m2) is preferably an amine compound having at least two amino groups (polyamine compound) and may be a diamine compound having two amino groups. Examples of the component (m2) include aromatic diamine compounds such as 4,4′-diaminodiphenylmethane, 4,4′-diamino-3,3′-dimethyldiphenylmethane, 3,3′-diethyl-4,4′-diaminodiphenylmethane, 4,4′-diaminodiphenyl ether, 4,4′-diaminodiphenylsulfone, 3,3′-diaminodiphenylsulfone, 4,4′-diaminodiphenyl ketone, 4,4′-diaminobiphenyl, 3,3′-dimethyl-4,4-diaminobiphenyl, 2,2′-dimethyl-4,4′-diaminobiphenyl, 3,3′-dihydroxybenzidine, 2,2-bis(3-amino-4-hydroxyphenyl) propane, 3,3′-dimethyl-5,5′-diethyl-4,4′-diaminodiphenylmethane, 2,2-bis(4-aminophenyl) propane, 2,2-bis[4-(4-aminophenoxy)phenyl]propane, 1,3-bis(3-aminophenoxy)benzene, 1,3-bis(4-aminophenoxy)benzene, 1,4-bis(4-aminophenoxy)benzene, 4,4′-bis(4-aminophenoxy) biphenyl, 1,3-bis[1-[4-(4-aminophenoxy)phenyl]-1-methylethyl]benzene, 1,4-bis [1-[4-(4-aminophenoxy)phenyl]-1-methylethyl]benzene, 4,4′-[1,3-phenylenebis(1-methylethylidene)]bisaniline, 4,4′-[1,4-phenylenebis(1-methylethylidene)]bisaniline, 3,3′-[1,3-phenylenebis(1-methylethylidene)]bisaniline, bis[4-(4-aminophenoxy)phenyl]sulfone, bis[4-(3-aminophenoxy)phenyl]sulfone, and 9,9-bis(4-aminophenyl) fluorene; and amine compounds having a siloxane skeleton.

Among these, the component (m2) may be an amine compound having a siloxane skeleton from the viewpoint of low thermal expansion properties. That is, the modified polymaleimide compound (M) may have a structural unit derived from a polymaleimide compound (m1) and a structural unit derived from an amine compound having a siloxane skeleton.

The component (m2) may be a compound represented by the following General Formula (2).

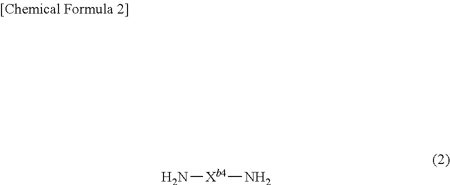

In Formula (2), X^{b4} represents a divalent organic group.

From the viewpoint of low thermal expansion properties, the component (m2) may include an amine compound having a siloxane skeleton, in which X^{b4} in the above-described General Formula (2) has a structural unit represented by the following General Formula (3). Furthermore, the component (m2) may include an amine compound having a siloxane skeleton, in which X^{b4} has a structural unit (or a group) represented by the following General Formula (4).

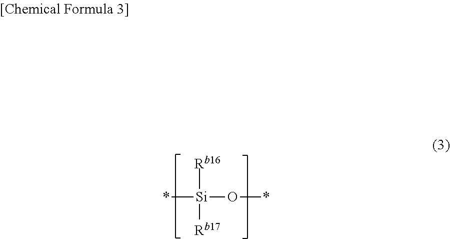

In Formula (3), R^{b16} and R^{b17} each independently represent an alkyl group having 1 to 5 carbon atoms, a phenyl group, or a substituted phenyl group. The symbol * represents a bonding position.

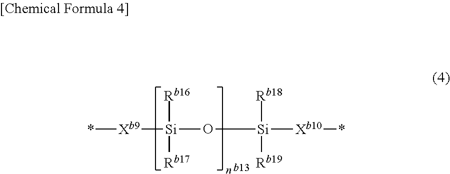

In Formula (4), R^{b16} and R^{b17} have the same meanings as R^{b16} and R^{b17} in the above-described General Formula (3), respectively, and a plurality of R^{b16}'s and R^{b17}'s present in the formula may each be the same or different. R^{b18} and R^{b19} each independently represent an alkyl group having 1 to 5 carbon atoms, a phenyl group, or a substituted phenyl group. X^{b9} and X^{b10} each independently represent a divalent organic group, and n^{b13} represents an integer of 2 to 100.

Examples of the substituent for the substituted phenyl group represented by R^{b16}, R^{b17}, R^{b18}, and R^{b19} include, for example, an alkyl group having 1 to 5 carbon atoms, an alkenyl group having 2 to 5 carbon atoms, and an alkynyl group having 2 to 5 carbon atoms.

Examples of the divalent organic group represented by X^{b9} and X^{b10} include an alkylene group, an alkenylene group, an alkynylene group, an arylene group, —O—, and a divalent linking group formed by combining these.

The content of the structural unit derived from the component (m1) in the modified polymaleimide compound (M) is not particularly limited; however, the content may be 50% to 95% by mass, may be 70% to 92% by mass, or may be 75% to 90% by mass.

The content of the structural unit derived from the component (m2) in the modified polymaleimide compound (M) is not particularly limited; however, the content may be 5% to 50% by mass, may be 8% to 30% by mass, or may be 10% to 25% by mass.

The total content of the structural unit derived from the component (m1) and the structural unit derived from the component (m2) in the modified polymaleimide compound (M) is not particularly limited; however, the total content may be 80% by mass or more, may be 90% by mass or more, may be 95% by mass or more, or may be 100% by mass (that is, composed only of the structural unit derived from the component (m1) and the structural unit derived from the component (m2)).

The content of the maleimide compound in the adhesive component may be 5% to 95% by mass, may be 10% to 90% by mass, or may be 15% to 85% by mass, based on the total amount of the adhesive component (total amount of solid content other than the conductive particles in the adhesive layer 10).

Examples of the curing accelerator include an imidazole-based compound, an organophosphorus-based compound, a tertiary amine, and a quaternary ammonium salt. Regarding the curing accelerator, one kind thereof may be used alone, or two or more kinds thereof may be used in combination. From the viewpoint that the temperature and time during use (for example, the heating temperature and heating time at the time of heating and pressure-bonding) can be arbitrarily adjusted, the adhesive component may contain an imidazole-based compound as a curing accelerator.

The content of the curing accelerator in the adhesive component may be 0.001% to 10% by mass based on the total amount of the adhesive component.

The adhesive component 14 may contain other components in addition to the above-mentioned thermosetting component. As the other components, the adhesive component 14 may further contain a filler, an antioxidant, a film-forming material, a softening agent, an anti-aging agent, a colorant, a flame retardant, a thixotropic agent, a coupling agent, and the like.

Examples of the filler include an inorganic filler and an organic filler. Examples of the inorganic filler include alumina, silica, titanium oxide, clay, calcium carbonate, aluminum carbonate, magnesium silicate, aluminum silicate, mica, short glass fibers, aluminum borate, and silicon carbide. Examples of the organic filler include silicone particles, methacrylate-butadiene-styrene particles, acrylic-silicone particles, polyamide particles, and polyimide particles. Regarding the filler, one kind thereof may be used alone, or two or more kinds thereof may be used in combination.

From the viewpoint of improving heat resistance, improving the mechanical properties, adjusting fluidity during use (for example, during heating and pressure-bonding), and the like, the adhesive component can contain silica particles as a filler.

The maximum diameter of the filler may be smaller than the particle size of the conductive particles 12 or may be 0.001 to 10 μm.

The content of the filler may be 5 parts by volume to 60 parts by volume with respect to 100 parts by volume of the adhesive component. When the content of the filler is 5 parts by volume to 60 parts by volume, satisfactory connection reliability tends to be obtained.

Examples of the antioxidant include quinone derivatives such as benzoquinone and hydroquinone; phenol derivatives (hindered phenol derivatives) such as 4-methoxyphenol and 4-t-butylcatechol; aminoxyl derivatives such as 2,2,6,6-tetramethylpiperidine-1-oxyl and 4-hydroxy-2,2,6,6-tetramethylpiperidine-1-oxyl; and hindered amine derivatives such as tetramethylpiperidyl methacrylate.

The content of the antioxidant may be 0.01% by mass to 5% by mass, or may be 0.1% by mass to 3% by mass, based on the total amount of the adhesive component.

As the film-forming material, a thermoplastic resin is suitably used, and examples thereof include a phenoxy resin, a polyvinyl formal resin, a polystyrene resin, a polyvinyl butyral resin, a polyester resin, a polyamide resin, a xylene resin, a polyurethane resin, a polyacrylic resin, and a polyester urethane resin. In addition, these polymers may contain a siloxane bond or a fluorine substituent. These resins can be used singly or as a mixture of two or more kinds thereof. Among the above-described resins, from the viewpoints of the adhesive strength, compatibility, heat resistance, and mechanical strength, a phenoxy resin may be used.

As the molecular weight of the thermoplastic resin is larger, film-forming properties are easily obtained, and the melt viscosity, which affects the fluidity of film, can be set in a wide range. The molecular weight of the thermoplastic resin may be 5000 to 150000, or may be 10000 to 80000, as the weight average molecular weight. When the weight average molecular weight is set to 5000 or more, satisfactory film-forming properties are likely to be obtained, and when the weight average molecular weight is set to 150000 or less, satisfactory compatibility with other components are likely to be obtained.

In the present disclosure, the weight average molecular weight refers to a value measured by gel permeation chromatography (GPC) under the following conditions, using a calibration curve based on polystyrene standards.

### (Measurement Conditions)

Apparatus: GPC-8020 manufactured by Tosoh Corporation
Detector: RI-8020 manufactured by Tosoh Corporation
Column: Gelpack GLA160S+GLA150S manufactured by Resonac Corporation
Sample concentration: 120 mg/3 mL
Solvent: Tetrahydrofuran
Injection volume: 60 μL
Pressure: 2.94×10⁶ Pa (30 kgf/cm²)
Flow rate: 1.00 mL/min

Furthermore, the content of the film-forming material may be 0.5% to 75% by mass, or may be 1% to 50% by mass, based on the total amount of the adhesive component.

From the viewpoint of improving the storage stability and improving the connection reliability, the adhesive component 14 may be substantially free of highly reactive radical polymerizable compounds such as an acrylic compound, a methacrylic compound, a styrene compound, and a vinyl compound. The phrase “substantially free of” implies that the content based on the total amount of the adhesive component is 1% by mass or less. The content of the above-described compound in the adhesive component may be 0.5% by mass or less, or may be 0% by mass, based on the total amount of the adhesive component.

From the viewpoint of forming a wiring layer that has sufficient crack resistance while having excellent connectivity under high temperature conditions, the adhesive layer 10 has a thermal expansion coefficient of 1.5% to 3% when the cured product is heated from 40° C. to 260° C. The thermal expansion coefficient can be determined by the following procedure.

### [Production of Cured Product]

(1) As a pre-heating evaluation sample, a portion of the adhesive layer is scraped off, and 0.60 g is weighed out.
(2) A silicone sheet having a length of 100 mm, a width of 100 mm, and a thickness of 1 mm is prepared, and a portion of this sheet is gouged out into a piece measuring 5 mm×40 mm×1 mm.
(3) The pre-heating evaluation sample that has been weighed out in (1) is inserted into the gouged-out portion of the silicone sheet.
(4) The silicone sheet inserted with the pre-heating evaluation sample is heated and pressurized under the conditions of 180° C. and 2 MPa for 60 minutes using a thermocompression bonding apparatus, to produce a cured product of the pre-heating evaluation sample.
   [Measurement of thermal expansion coefficient of cured Product]
(1) The cured product of the pre-heating evaluation sample produced as described above is cut out into a piece measuring 5 mm×5 mm×1 mm, and an evaluation sample is produced.
(2) Using a thermomechanical analysis (TMA) apparatus (measurement mode: compression), the amount of change in the thickness when the evaluation sample is heated from 40° C. to 260° C. at a temperature increase rate of 5° C./min is measured, and the thermal expansion coefficient is calculated by the following expression.

$$Thermal expansion coefficient ( \% ) = ( Thickness at 260 ° C . - thickness at 40 ° C . ) \times 100 / ( thickness at 40 ° C . )$$

When the above-described thermal expansion coefficient is 1.5% or more, it becomes easier to improve the crack resistance of the adhesive layer, and when the above-described thermal expansion coefficient is 3% or less, the wiring layer can have excellent connectivity under high humidity conditions. From the viewpoint of achieving both the crack resistance of the adhesive layer and satisfactory connectivity of the wiring layer under high temperature conditions to a high level, the above-described thermal expansion coefficient may be 1.6% to 2.9%, or may be 1.7% to 2.8%.

The above-described thermal expansion coefficient can be adjusted by, for example, the following method.
(a) Examples of a method for increasing the thermal expansion coefficient include increasing the amount of a thermoplastic resin component, reducing the amount of a filler, adding low-elasticity components such as a rubber component and an elastomer component, and reducing the amount of a crosslinkable component during curing.
(b) Examples of a method for decreasing the thermal expansion coefficient include reducing the amount of a thermoplastic resin component, increasing the amount of a filler, reducing the amount of a low-elasticity component, and increasing the amount of a crosslinkable component during curing.

From the viewpoint of making it difficult for resistance unevenness to occur, the reaction ratio when the adhesive layer 10 is heated at 180° C. for 5 minutes may be 90% or less, may be 85% or less, may be 80% or less, or may be 70% or less.

The above-described reaction ratio means a value that is determined by the following measurement method.

[Measurement of Reaction Ratio when Heated at 180° C. For 5 Minutes]

A portion of the adhesive layer is scraped off, and two 5-mg pre-heating evaluation samples are obtained. Next, one of the pre-heating evaluation samples is heated at 180° C. for 5 minutes to obtain a post-heating evaluation sample. For each of the pre-heating evaluation sample and the post-heating evaluation sample, the DSC calorific value is measured using a differential scanning calorimetry (DSC) apparatus (product name DSC7, manufactured by PERKIN ELMER, Inc.) under a nitrogen gas stream in a measurement temperature range of 30° C. to 250° C. at a temperature increase rate of 2° C./min. Based on the measured DSC calorific value, the reaction ratio when the sample is heated at 180° C. for 5 minutes is determined from the following expression.

$$Reaction ratio = ( C x - C y ) \times 100 / C x$$

wherein Cx represents the DSC calorific value (J/g) of the pre-heating evaluation sample, and Cy represents the DSC calorific value (J/g) of the post-heating evaluation sample.

The reaction ratio of the adhesive layer when heated at 180° C. for 5 minutes can be made small by, for example, adding the above-mentioned phenol resin and maleimide compound, not adding a curing accelerator, or selecting a curing accelerator having a high reaction initiation temperature.

From the viewpoint of making it difficult for resistance unevenness to occur, the ratio [Dp/T] of the average particle size Dp of the copper particles and the thickness T of the adhesive layer may be 0.56 to 1.2, may be 0.6 to 1.15, or may be 0.65 to 1.1.

The thickness of the adhesive layer may be 1 to 70 μm, may be 2 to 60 μm, or may be 3 to 50 μm.

### [Configuration of Metal Layer]

The surface roughness Rz of one surface and the opposite surface of the metal layer 20 may be equal or may be different. The metal layer 20 has, for example, a thickness of 5 μm to 200 μm. The thickness of the metal layer as used herein is a thickness including the surface roughness Rz. The metal layer 20 is, for example, a copper foil, an aluminum foil, a nickel foil, stainless steel, titanium, or platinum.

The adhesive layer 10 is disposed on a first surface 20a of the metal layer 20. The surface roughness Rz of the first surface 20a of the metal layer 20 may be 0.3 μm or more, may be 0.5 μm or more, or may be 1.0 μm or more. Furthermore, the surface roughness Rz of the first surface 20a of the metal layer may be 50 μm or less, may be 40 μm or less, may be 30 μm or less, may be 20 μm or less, may be smaller than 20 μm, may be 17 μm or less, may be 10 μm or less, may be 8.0 μm or less, may be 5.0 μm or less, or may be 3.0 μm or less. The surface roughness Rz of the first surface 20a of the metal layer 20 may be, for example, 0.3 μm or more and 20 μm or less, or may be 0.3 μm or more and 20 μm or less, and more particularly, the surface roughness Rz may be 0.5 μm or more and 10 μm or less. The surface roughness Rz of a second surface 20b of the metal layer 20 may be, for example, 20 μm or more, and the surface roughness Rz of the second surface 20b may be rougher than the surface roughness Rz of the first surface 20a, may be the same surface roughness as the first surface 20a, or does not have to be rougher than the surface roughness Rz of the first surface 20a. When the surface roughness Rz of the first surface 20a of the metal layer 20 is too smooth (for example, the surface roughness Rz is 0.2 μm), the adhesiveness between the metal layer 20 and the adhesive layer 10 may not be maintained over a long period of time, and peeling may occur. For this reason, the surface roughness Rz of the first surface 20a of the metal layer 20 may be 0.3 μm or more. However, the surface roughness Rz of the first surface 20a of the metal layer 20 may be made smaller than 0.3 μm by employing a material or connection configuration that can ensure adhesiveness.

The surface roughness Rz means the 10-point average roughness Rzjis measured according to the method specified in the JIS Standard (JIS B 0601-2001) and refers to a value measured using a commercially available surface roughness profile measuring device. For example, measurement can be made using a nano search microscope (“SFT-3500” manufactured by Shimadzu Corporation).

Here, the relation of the surface roughness Rz of the first surface 20a of the metal layer 20 with respect to the average particle size Dp of the conductive particles 12 will be described below. In the present embodiment, the “surface roughness/average particle size”, which is the ratio of the surface roughness Rz of the first surface 20a of the metal layer 20 with respect to the average particle size Dp of the conductive particles 12, may be 0.03 or more, may be 0.04 or more, may be 0.05 or more, may be 0.06 or more, may be 0.1 or more, may be 0.2 or more, may be 0.3 or more, may be 0.5 or more, or may be 1 or more. Furthermore, the “surface roughness/average particle size”, which is the ratio of the surface roughness Rz of the first surface 20a of the metal layer 20 with respect to the average particle size Dp of the conductive particles 12, may be 3 or less, may be 2 or less, may be 1.7 or less, or may be 1.5 or less. The “surface roughness/average particle size”, which is the ratio of the surface roughness Rz of the first surface 20a of the metal layer 20 with respect to the average particle size Dp of the conductive particles 12, may be, for example, 0.05 or more and 3 or less, and more particularly, may be 0.06 or more and 2 or less. In the present embodiment, the surface roughness Rz of the first surface 20a of the metal layer 20 and the average particle size Dp of the conductive particles 12 may be controlled such that the “surface roughness/average particle size”, which is the ratio of the surface roughness Rz of the first surface 20a of the metal layer 20 with respect to the average particle size Dp of the conductive particles 12, is in the range of 0.05 to 3.

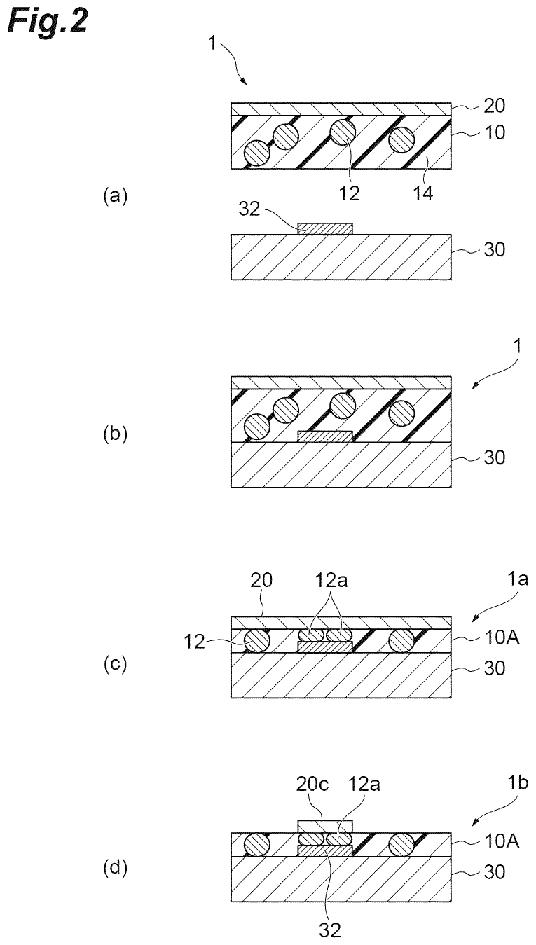

According to another aspect, the present disclosure relates to a method for forming a wiring layer using a member for wiring formation. A method for forming a wiring layer using the above-mentioned member for wiring formation 1 will be described with reference to FIG. 2. (a) to (d) of FIG. 2 are drawings showing a method for forming a wiring layer using the member for wiring formation shown in FIG. 1.

First, as shown in (a) of FIG. 2, a member for wiring formation 1 is provided. In addition, a base material 30 on which a wiring 32 is formed is provided. Then, the member for wiring formation 1 is disposed such that the adhesive layer 10 side of the member for wiring formation 1 faces the base material 30. Thereafter, as shown in (b) of FIG. 2, lamination is performed so as to cover the wiring 32, and the member for wiring formation 1 is stuck onto the base material 30.

Subsequently, as shown in (c) of FIG. 2, the member for wiring formation 1 is subjected to predetermined heating and pressurization, and is pressure-bonded to the base material 30. At this time, when the first surface 20a of the metal layer 20 of the member for wiring formation 1 is flat, the conductive particles 12 that need to secure conductivity can be more reliably deformed into conductive particles 12a having a flat shape. Then, in the pressure-bonded member for wiring formation 1a, conductive particles 12a that have been flattened (as a result, the insulating layer is destroyed, and the conductive part is exposed) are arranged on the wiring 32, and reliable electrical conduction is achieved between the metal layer 20 and the wiring 32. At this time, the adhesive layer 10 is also crushed to become a thinner adhesive layer 10A.

Subsequently, as shown in (d) of FIG. 2, the metal layer 20 is subjected to a predetermined patterning treatment (for example, an etching treatment) and is processed into a predetermined wiring pattern 20c (another wiring). At this time, the second surface 20b of the metal layer 20 may be subjected to a treatment for making a smooth surface. The above-mentioned treatments of (a) to (d) of FIG. 2 may be repeated a predetermined number of times to form a wiring layer.

That is, a method for forming a wiring layer using a member for wiring formation includes: a step of providing a member for wiring formation; a step of providing a base material on which a wiring is formed; a step of disposing the member for wiring formation on the surface of the base material on which a wiring is formed so that the member for wiring formation covers the wiring, such that the adhesive layer side faces the substrate; a step of heating and pressure-bonding the member for wiring formation to the base material; and a step of performing a patterning treatment on the metal layer.

In this manner, a wiring-formed member 1b is formed. This wiring-formed member 1b includes: the base material 30 having the wiring 32; and a cured product of the adhesive component 14 (adhesive layer of the heated and pressure-bonded member for wiring formation) of the member for wiring formation 1 disposed on the base material 30 to cover the wiring 32. In this wiring-formed member 1b, the wiring 32 and the metal layer 20 of the member for wiring formation 1 or a wiring 20c formed (for example, etching-processed) from the metal layer 20 are electrically connected by the conductive particles 12a. When the treatments in (a) to (d) of FIG. 2 are repeated a predetermined number of times, the wiring-formed member 1b may be configured to have a plurality of wiring layers (layers in which the above-mentioned wirings are connected to each other).

In this way, according to the method for forming a wiring layer using the member for wiring formation 1 according to the present embodiment, the process of forming a wiring layer that connects between wirings can be simplified as compared with conventional processes that perform laser processing, field plating treatments, and the like. Furthermore, the wiring layer thus formed can be easily made thinner.

Furthermore, according to the method for forming a wiring layer using the member for wiring formation 1 according to the present embodiment, the adhesive layer 10 has the above-mentioned reaction ratio, and when the ratio [Dp/T] of the average particle size Dp of the conductive particles 12 and the thickness T of the adhesive layer 10 is 0.56 to 1.2, a wiring layer in which resistance unevenness is suppressed can be formed.

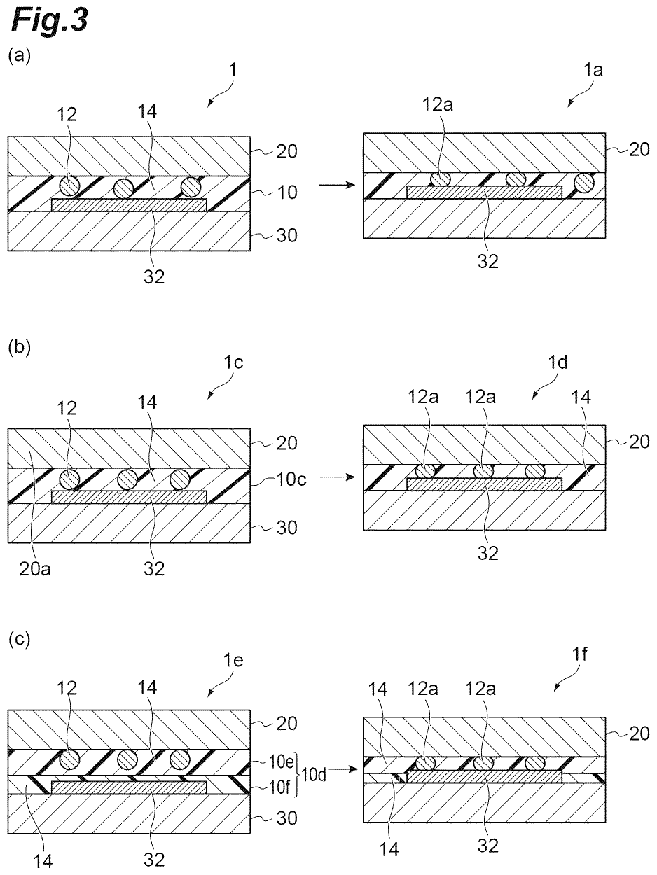

Thus, the embodiment of the present disclosure has been described in detail; however, the present disclosure is not limited to the above-described embodiment and can be applied to various embodiments. For example, in the above-described embodiment, as shown in (a) of FIG. 3, the member for wiring formation 1 is configured such that the conductive particles 12 are randomly or evenly dispersed within the adhesive layer 10; however, as shown in (b) of FIG. 3, the conductive particles 12 may also be arranged (unevenly distributed) on the metal layer 20 side. In this case, in the adhesive layer 10, the conductive particles 12 are not exposed at the second surface 10b on the opposite side of the metal layer 20, and the thickness of the adhesive layer 10 present between the conductive particles 12 and the first surface 20a of the metal layer 20 may be 0 μm or greater than 0.1 μm and 1 μm or less. In this case, since the conductive particles 12 are arranged on the metal layer 20 side, it is possible to crush the conductive particles 12 more reliably into a flat shape by the metal layer 20. Furthermore, by unevenly distributing the conductive particles 12 on the metal layer 20 side in this manner, the capture rate of the conductive particles 12 to the wiring (electrodes) and the like can be improved. That is, conduction can be made more stable. The distance between the above-mentioned conductive particles 12 and the first surface 20a of the metal layer 20 (thickness of the adhesive layer 10 present therebetween) means the shortest distance from the surface in contact with the adhesive layer 10 of the metal layer 20 to the surface of the conductive particles 12, and the distance is, for example, the average value calculated for any 30 points. Furthermore, this distance is measured by sandwiching the member for wiring formation between two sheets of glass (thickness: about 1 mm), pouring in a resin composition composed of 100 g of a bisphenol A type epoxy resin (trade name: JER811, manufactured by Mitsubishi Chemical Corporation) and 10 g of a curing agent (trade name: EPOMOUNT Hardener, manufactured by Refine Tec, Ltd.), subsequently performing cross-section polishing using a polishing machine, and making measurement using a scanning electron microscope (SEM, trade name: SE-8020, manufactured by Hitachi High-Tech Science Corporation).

Furthermore, as shown in (c) of FIG. 3, an adhesive layer 10d may be formed dividedly into a first adhesive layer 10e and a second adhesive layer 10f. The adhesive component constituting the first adhesive layer 10e and the second adhesive layer 10f may be the same as the adhesive component constituting the above-mentioned adhesive layer 10; however, the difference is in that the second adhesive layer 10f does not have the conductive particles 12 dispersed therein, that is, does not contain the conductive particles 12. Even in this case, when the adhesive layer 10d has the above-mentioned reaction ratio, and the ratio [Dp/T] of the average particle size Dp of the conductive particles 12 and the thickness T of the adhesive layer 10 is 0.56 to 1.2, a wiring layer in which resistance unevenness is suppressed can be formed. In the member for wiring formation 1e according to this modification example, the conductive particles 12 are dispersed, that is, included, in the first adhesive layer 10e. In this case, similarly to the modification example shown in (b) of FIG. 3, since the conductive particles 12 are arranged on the metal layer 20 side, in a wiring layer 1f, it is possible to crush the conductive particles more reliably into a flat shape by the metal layer 20. Furthermore, by unevenly distributing the conductive particles 12 on the metal layer 20 side in this manner, the capture rate of the conductive particles 12 in the wiring (electrodes) and the like can be improved. That is, conduction can be made more stable.

Furthermore, the members for wiring formation 1, 1c, and 1e may further include a release film. The release film may be adhered to the opposite side of the surface of the adhesive layer 10, 10c, or 10d to which the metal layer 20 is adhered; may be adhered to the opposite side of the surface of the metal layer 20 to which the adhesive layer 10, 10c, or 10d is adhered; or may be adhered to both of these. Furthermore, the first surface 20a of the metal layer 20 may be adhered to the adhesive layer 10 10c, or 10d. In this case, it is easier to handle the member for wiring formation, and the operation efficiency when a wiring layer is formed using the member for wiring formation can be improved.

Furthermore, a case in which the member for wiring formation is a member formed by bonding the adhesive layer 10 and the metal layer 20 together has been described above as an example; however, the member for wiring formation in the present embodiment may be configured as a set product in which the adhesive layer 10 and the metal layer 20 are provided as separate entities, and the adhesive layer 10 can be adhered to the first surface 20a of the metal layer 20 when put to use. In this case, since the adhesive layer 10 and the metal layer 20 can be prepared separately (as a set of the member for wiring formation), it is possible to improve the degree of freedom of work when producing a wiring layer using the member for wiring formation, such as by selecting a member for wiring formation having a more optimal material configuration.

The metal layer-attached adhesive film of the present embodiment may be such that the adhesive layer includes a first adhesive layer containing copper particles and an adhesive component, and a second adhesive layer containing an adhesive component. Such a metal layer-attached adhesive film can also be used to form wiring. Hereinafter, the details of the metal layer-attached adhesive film having the above-described configuration will be described by referring to a case of using the metal layer-attached adhesive film as a member for wiring formation.

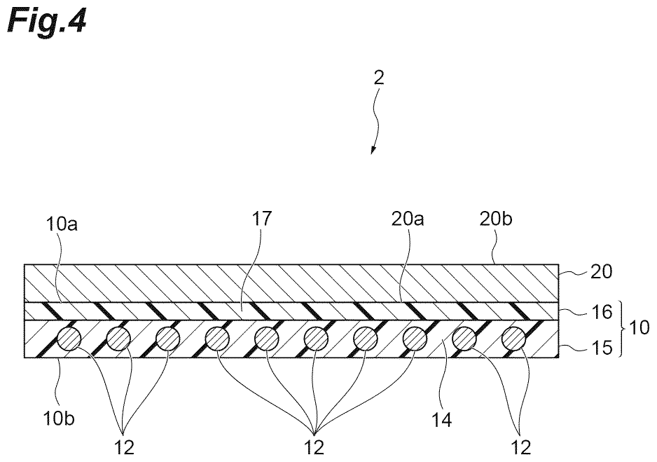

FIG. 4 is a cross-sectional view showing the member for wiring formation according to another embodiment of the present disclosure. The member for wiring formation 2 shown in FIG. 4 is configured to include an adhesive layer 10 containing conductive particles 12 and a metal layer 20. The adhesive layer 10 includes a first adhesive layer 15 containing conductive particles 12 and an adhesive component 14, and a second adhesive layer 16 containing an adhesive component 17.

The first adhesive layer 15 contains conductive particles 12 and an insulating adhesive component 14 in which the conductive particles 12 are dispersed. The adhesive component 14 is similar to the adhesive component described above.

The second adhesive layer 16 contains an insulating adhesive component 17. The insulating adhesive component 17 in the second adhesive layer 16 may be the same as or different from the adhesive component 14. The adhesive component 17 in the second adhesive layer 16 is defined as the solid content other than the conductive particles. The second adhesive layer 16 may be in a B-stage state, that is, a semi-cured state, before a wiring layer is formed using the member for wiring formation 2.

In the present embodiment, the reactivity of the first adhesive layer 15 and the second adhesive layer 16 is adjusted so that the adhesive layer 10 has the above-described reaction ratio, and the average particle size of the conductive particles 12 and the thicknesses of the first adhesive layer 15 and the second adhesive layer 16 may be adjusted such that the ratio [Dp/T] of the average particle size Dp of the conductive particles 12 and the thickness T of the adhesive layer 10 is in the above-mentioned range.

The thickness d1 of the first adhesive layer 15 may be 0.56 to 1.2 times, may be 0.56 to 1.0 times, or may be 0.56 to 0.80 times, the average particle size Dp of the conductive particles 12.

The thickness of the first adhesive layer 15 may be 1 to 70 μm, may be 1 to 60 μm, or may be 1 to 50 μm.

The thickness of the second adhesive layer 16 may be 0 to 50 μm, may be 0 to 40 μm, or may be 0 to 30 μm.

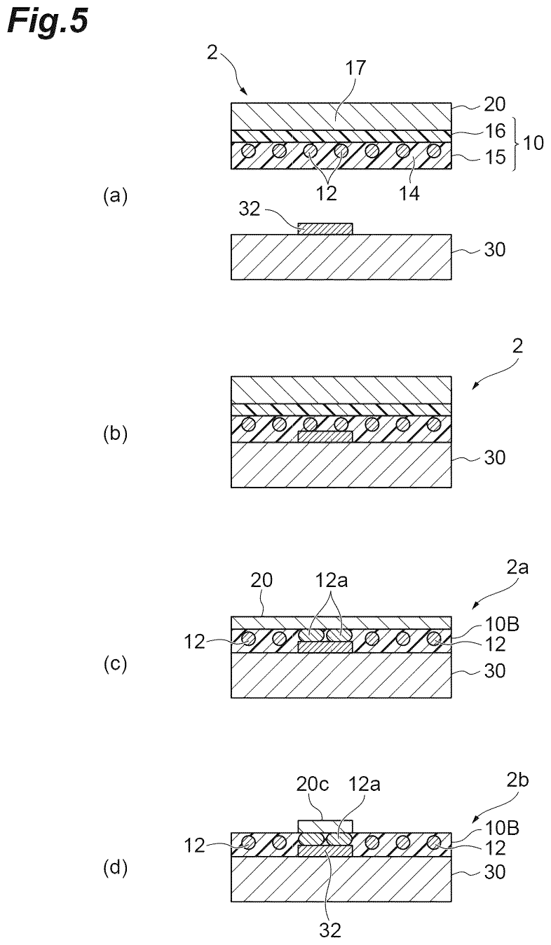

Next, a method for forming a wiring layer using the above-mentioned member for wiring formation 2 will be described with reference to FIG. 5. (a) to (d) of FIG. 5 are drawings showing a method for forming a wiring layer using the member for wiring formation shown in FIG. 4.

First, as shown in (a) of FIG. 5, a member for wiring formation 2 is provided. In addition, a base material 30 on which a wiring 32 is formed is provided. Then, the member for wiring formation 2 is disposed such that the adhesive layer 10 side of the member for wiring formation 2 faces the base material 30. Thereafter, as shown in (b) of FIG. 5, lamination is performed so as to cover the wiring 32, and the member for wiring formation 2 is stuck onto the base material 30.

Subsequently, as shown in (c) of FIG. 5, the member for wiring formation 2 is subjected to predetermined heating and pressurization, and is pressure-bonded to the base material 30. At this time, when the first surface 20a of the metal layer 20 of the member for wiring formation 2 is flat, the conductive particles 12 that need to secure conductivity can be more reliably deformed into conductive particles 12a having a flat shape. Then, in the pressure-bonded member for wiring formation 2a, conductive particles 12a that have been flattened (as a result, the insulating layer is destroyed, and the conductive part is exposed) are arranged on the wiring 32, and satisfactory electrical conduction is achieved between the metal layer 20 and the wiring 32. At this time, the adhesive layer 10 is also crushed to become a thinner adhesive layer 10B. Furthermore, since the adhesive layer 10 includes a first adhesive layer 15 in which conductive particles are contained in an adhesive component, and a second adhesive layer 16, satisfactory insulation reliability is achieved in the thickness direction in places where conductive connection is not desired.

Subsequently, as shown in (d) of FIG. 5, the metal layer 20 is subjected to a predetermined patterning treatment (for example, an etching treatment) and is processed into a predetermined wiring pattern 20c (another wiring). At this time, the second surface 20b of the metal layer 20 may be subjected to a treatment for making a smooth surface. The above-mentioned treatments in (a) to (d) of FIG. 5 may be repeated a predetermined number of times to form a wiring layer.

That is, a method for forming a wiring layer using a member for wiring formation includes: a step of providing a member for wiring formation; a step of providing a base material on which a wiring is formed; a step of disposing the member for wiring formation on the surface of the base material, on which a wiring is formed so that the member for wiring formation covers the wiring, such that the adhesive layer side faces the substrate; a step of heating and pressure-bonding the member for wiring formation to the base material; and a step of performing a patterning treatment on the metal layer.

In this manner, a wiring-formed member 2b is formed. This wiring-formed member 1b includes: the base material 30 having the wiring 32; and a cured product of the first adhesive layer 15 and the second adhesive layer 16 (adhesive layers of the heated and pressure-bonded member for wiring formation) of the member for wiring formation 2 disposed on the base material 30 to cover the wiring 32. In this wiring-formed member 2b, the wiring 32 and the metal layer 20 of the member for wiring formation 2 or a wiring pattern 20c formed (for example, etching-processed) from the metal layer 20 are electrically connected by the conductive particles 12a. When the treatments in (a) to (d) of FIG. 5 are repeated a predetermined number of times, the wiring-formed member 2b may be configured to have a plurality of wiring layers (layers in which above-mentioned wirings are connected to each other).

In this way, according to the method for forming a wiring layer using the member for wiring formation 2 according to the present embodiment, the process of forming a wiring layer that connects between wirings can be simplified as compared with conventional processes that perform laser processing, field plating treatments, and the like. Furthermore, the wiring layer thus formed can be easily made thinner.

Furthermore, according to the method for forming a wiring layer using the member for wiring formation 2 according to the present embodiment, the adhesive layer 10 has the above-mentioned reaction ratio, and when the ratio [Dp/T] of the average particle size Dp of the conductive particles 12 and the thickness T of the adhesive layer 10 is 0.56 to 1.2, a wiring layer in which resistance unevenness is suppressed can be formed.

Furthermore, according to the method for forming a wiring layer using the member for wiring formation 2 according to the present embodiment, the degree of freedom in the design of a wiring pattern when the wiring layer is formed can be sufficiently secured by the following effects.
(i) As the adhesive layer 10 includes the second adhesive layer 16, even in a case where a wiring layer formed by patterning the metal layer 20 has a part in the lamination direction (or thickness direction of the adhesive layer) in which conductive connection is not desired, it becomes easy to ensure insulation reliability in that portion.
(ii) In a wiring layer formed by patterning the metal layer 20 or in a rewiring formed separately, it is difficult for the conductive particles 12 to come into contact with parts other than the parts that are conductively connected, and it becomes easy to suppress transmission losses in the wiring caused by contact of the conductive particles.

The above-described effects will be described with reference to the drawings.

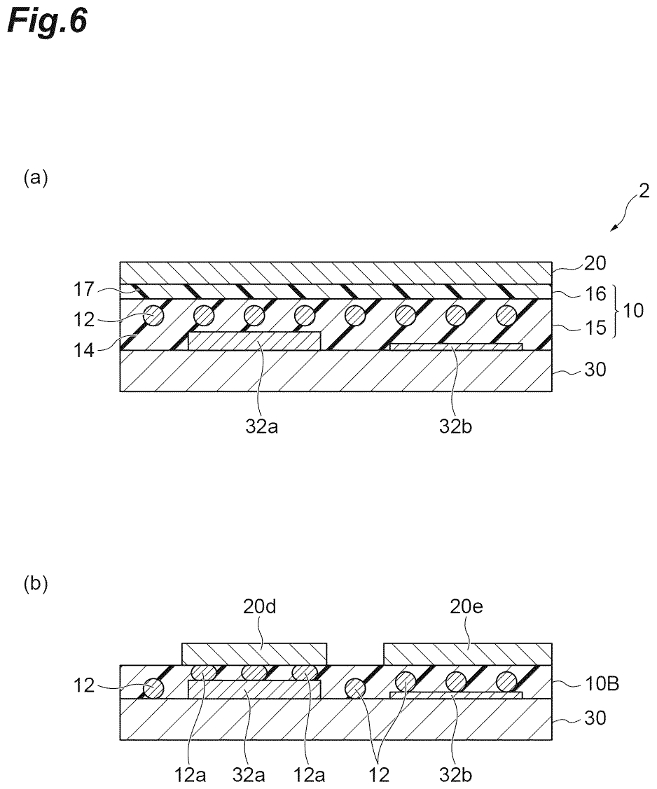

(a) and (b) of FIG. 6 are cross-sectional views for describing an example of a case in which a wiring layer is formed using the member for wiring formation 2 according to the present embodiment.

(a) of FIG. 6 shows a state in which a base material 30 having a wiring pattern 32a and a wiring pattern 32b is provided, and the member for wiring formation 2 is disposed on a surface of the base material 30 on which the wiring patterns are formed so that the member for wiring formation covers the wiring patterns 32a and 32b, such that the adhesive layer 10 side faces the base material 30. Thereafter, by going through a step of heating and pressure-bonding the member for wiring formation 2 to the base material 30 and a step of performing a patterning treatment on the metal layer 20, a wiring-formed member is obtained in which a wiring pattern 20d that is conductively connected to the wiring pattern 32a, and a wiring pattern 20e that is not intended to be conductively connected to the wiring pattern 32b are formed as shown in (b) of FIG. 6.

Here, since the adhesive layer 10 of the member for wiring formation 2 includes the first adhesive layer 15 that contains the conductive particles 12 and the adhesive component 14, and the second adhesive layer 16 that does not contain the conductive particles but contains the adhesive component 17, an adhesive layer 18a can be provided with a thickness that, when the adhesive layer 18a is pressure-bonded, ensures satisfactory conduction between wirings of the wiring pattern 20d and the wiring pattern 32a through the conductive particles 12 while ensuring a distance in which conduction by the conductive particles 12 does not occur between the wiring pattern 20e and the wiring pattern 32b where conductive connection is not desired. As a result, the wiring pattern 20e and the wiring pattern 32b are not conductively connected, and insulation reliability in the thickness direction of the adhesive layer can be ensured.

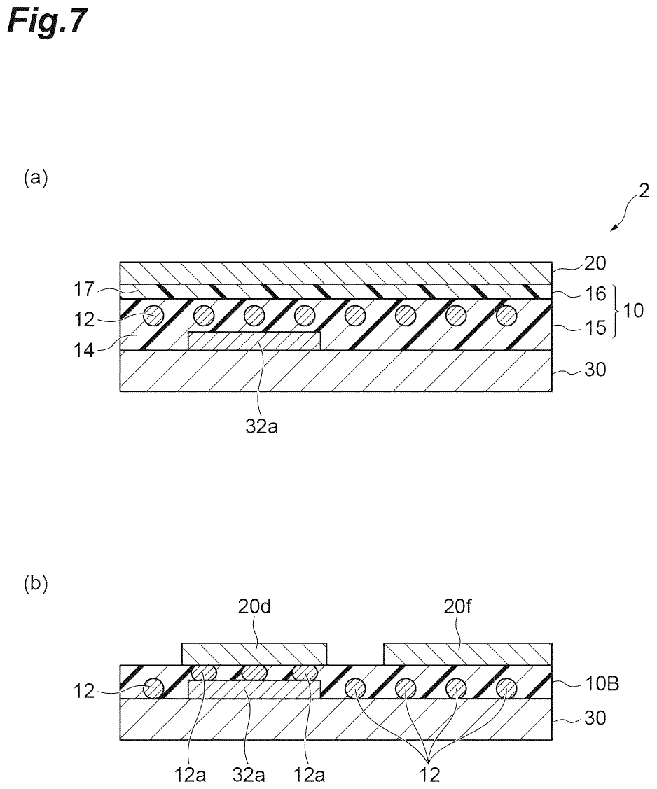

(a) and (b) of FIG. 7 are cross-sectional views for describing another example in a case where a wiring layer is formed using the member for wiring formation 2 according to the present embodiment.

(a) of FIG. 7 shows a state in which a base material 30 having a wiring pattern 32a is provided, and the member for wiring formation 2 is disposed on the surface of the base material on which the wiring pattern is formed so that the member for wiring formation covers the wiring pattern 32a, such that the adhesive layer 10 side faces the base material 30. Thereafter, by going through a step of heating and pressure-bonding the member for wiring formation 2 to the base material 30 and a step of performing a patterning treatment on the metal layer 20, a wiring-formed member is obtained in which a wiring pattern 20d that is conductively connected to the wiring pattern 32a, and a wiring pattern 20f that is not conductively connected to the wiring pattern 32a (or a part that is not conductively connected in the wiring pattern) are formed as shown in (b) of FIG. 7.

Here, since the adhesive layer 10 of the member for wiring formation 2 includes the first adhesive layer 15 that contains the conductive particles 12 and the adhesive component 14, and the second adhesive layer 16 that does not contain the conductive particles but contains the adhesive component 17, an adhesive layer 18a can be provided in which, when the adhesive layer 18a is pressure-bonded, satisfactory conduction is ensured between the wiring pattern 20d and the wiring pattern 32a through the conductive particles 12 while the wiring pattern 20f and the conductive particles 12 are not in contact. As a result, transmission loss of the wiring caused by contact with the conductive particles can be suppressed in the wiring pattern 20f. In particular, in the member for wiring formation 2, since the metal layer 20, the second adhesive layer 16, and the first adhesive layer 15 are laminated in this order, it becomes easy to prevent contact between the wiring pattern 20f and the conductive particles 12.

In the method shown in FIG. 7, the wiring pattern 20f may be formed by a step of performing a patterning treatment on the metal layer 20 and a step of forming a rewiring.

In the first adhesive layer 15 of the member for wiring formation 2 shown in FIG. 4, the conductive particles 12 are locally arranged; however, the conductive particles 12 may be randomly or evenly dispersed within the adhesive component 14.

Furthermore, in the first adhesive layer 15 of the member for wiring formation 2, the conductive particles 12 may be locally arranged on the second adhesive layer 16 side, or the conductive particles 12 may be locally arranged on the opposite side of the second adhesive layer 16 side (second surface 10b side of the adhesive layer 10).

Furthermore, the second adhesive layer 16 of the member for wiring formation 2 does not contain the conductive particles; however, the second adhesive layer 16 may contain a portion of the main particle bodies of the conductive particles 12 (in other words, does not have to contain the entirety of the main particle bodies of the conductive particles 12).

Furthermore, the adhesive layer 10 of the member for wiring formation 2 may be composed of two layers, namely, the first adhesive layer 15 and the second adhesive layer 16, or may be composed of three or more layers, including a layer other than the first adhesive layer 15 and the second adhesive layer 16 (for example, a third adhesive layer). The third adhesive layer may be a layer having the same composition as the above-mentioned composition for the first adhesive layer 15 or the second adhesive layer 16, or may be a layer having the same thickness as the above-mentioned thickness for the first adhesive layer 15 or the second adhesive layer 16. For example, the member for wiring formation 2 may be configured to have a metal layer, a third adhesive layer, a second adhesive layer, and a first adhesive layer laminated in this order, or may be configured to have a metal layer, a second adhesive layer, a first adhesive layer, and a third adhesive layer laminated in this order; however, the configuration is not limited.

Furthermore, the member for wiring formation 2 may further include a release film. The release film may be adhered to the opposite side of the surface of the adhesive layer 10 to which the metal layer 20 is adhered (second surface 10b side of the adhesive layer 10); may be adhered to the opposite side (second surface 20b side of the metal layer 20) of the surface of the metal layer 20 to which the adhesive layer 10 is adhered (first surface 20a of the metal layer); or may be adhered to both of these. In this case, it is easier to handle the member for wiring formation, and the operation efficiency when a wiring layer is formed using the member for wiring formation can be improved.

Furthermore, a case in which the member for wiring formation is a member formed by adhering the adhesive layer 10 and the metal layer 20 together has been described above as an example; however, the member for wiring formation 2 in the present embodiment may be configured as a set product in which the adhesive layer 10 and the metal layer 20 are provided as separate entities, and the adhesive layer 10 can be adhered to the first surface 20a of the metal layer 20 when put to use. In this case, since the adhesive layer 10 and the metal layer 20 can be prepared separately (as a set of the member for wiring formation), it is possible to improve the degree of freedom of work when producing a wiring layer using the member for wiring formation, such as by selecting a member for wiring formation having a more optimal material configuration.

The adhesive film according to an embodiment of the present disclosure contains conductive particles and a thermosetting resin composition, and the thermal expansion coefficient when a cured product of the adhesive film is heated from 40° C. to 260° C. is 1.5% to 3%. The cured product of the adhesive film can also be produced in the same manner as in the case of the above-described cured product of the adhesive layer, and the thermal expansion coefficient can also be measured in the same manner.

The adhesive film according to the present embodiment may have a configuration similar to that of the adhesive layer in the above-mentioned member for wiring formation.

The adhesive film according to the present embodiment can be produced by the following method. Specifically, first, a thermosetting resin composition and conductive particles are added to a solvent (organic solvent) and dissolved or dispersed by stirred mixing, kneading, or the like to prepare a varnish composition (varnish-like adhesive composition). Thereafter, the varnish composition can be applied on a base material that has been subjected to a release treatment, using a knife coater, a roll coater, an applicator, a comma coater, a die coater, or the like, and then the solvent can be volatilized by heating to form an adhesive film on the base material.

As the solvent used for the preparation of the varnish composition, a solvent having the characteristics capable of uniformly dissolving or dispersing each component may be used. Examples of such a solvent include toluene, acetone, methyl ethyl ketone, methyl isobutyl ketone, ethyl acetate, propyl acetate, and butyl acetate. These solvents can be used singly or in combination of two or more kinds thereof. Stirred mixing and kneading at the time of preparing the varnish composition can be carried out using, for example, a stirrer, a Raikai mixer, a three-roll, a ball mill, a bead mill, or a Homodisper.

The base material is not particularly limited as long as it has heat resistance that can withstand the heating conditions when the solvent is volatilized, and for example, base materials (for example, films) made of oriented polypropylene (OPP), polyethylene terephthalate (PET), polyethylene naphthalate, polyethylene isophthalate, polybutylene terephthalate, polyolefin, polyacetate, a polycarbonate, polyphenylene sulfide, polyamide, polyimide, cellulose, ethylene-vinyl acetate copolymer, polyvinyl chloride, polyvinylidene chloride, synthetic rubber, liquid crystal polymer, and the like can be used.

The adhesive film according to the present embodiment can be used for the connection of circuit members, and can be suitably used as an adhesive film for circuit connection intended for connecting a first circuit member having a first electrode (for example, a first circuit member in which a first circuit electrode is formed on a principal surface of a first substrate) and a second circuit member having a second electrode (for example, a second circuit member in which a second circuit electrode is formed on a principal surface of a second substrate) in a state in which the first electrode and the second electrode (the first circuit electrode and the second circuit electrode) are arranged to face each other. With the adhesive film according to the present embodiment, the conductivity between electrodes in a circuit connection structure can be improved.

Examples of the first circuit member and the second circuit member include chip components such as a semiconductor chip, a resistor chip, and a capacity chip; and substrates such as a printed board.

### EXAMPLES

Hereinafter, the present disclosure will be described more specifically by way of Examples. However, the present disclosure is not intended to be limited to these Examples.

### <Preparation of Adhesive Component (Thermosetting Resin Composition)>

The following thermosetting components and filler were provided as adhesive components.

### (Thermosetting Component)

Epoxy resin A: NC-3000H (biphenyl aralkyl type epoxy resin, manufactured by Nippon Kayaku Co., Ltd., trade name, epoxy equivalent: 289 g/eq)
Epoxy resin B: YL983U (bisphenol F type epoxy resin, manufactured by Mitsubishi Chemical Corporation, trade name, epoxy equivalent: 170 g/eq)
Epoxy resin C: HP-4700 (naphthalene type polyfunctional epoxy resin, manufactured by DIC Corporation, trade name, epoxy equivalent: 165 g/eq)
Epoxy resin D: jER-630 (polyfunctional epoxy resin, manufactured by Mitsubishi Chemical Corporation, trade name, epoxy equivalent: 98 g/eq)
Phenol resin A; KA-1160 (cresol novolac type phenol resin, manufactured by DIC Corporation, trade name, hydroxyl group equivalent: 117 g/eq) The hydroxyl group equivalent of the phenol resin was determined by the following measurement method.
Phenol resin B: KA-1163 (cresol novolac type phenol resin, manufactured by DIC Corporation, trade name, hydroxyl group equivalent: 118 g/eq) The hydroxyl group equivalent of the phenol resin was determined by the following measurement method.
Phenol resin C: KA-1165 (cresol novolac type phenol resin, manufactured by DIC Corporation, trade name, hydroxyl group equivalent: 119 g/eq) The hydroxyl group equivalent of the phenol resin was determined by the following measurement method.
Phenoxy resin A: YP-70 (BPA/BPF copolymer type, manufactured by NIPPON STEEL Chemical & Material Co., Ltd., trade name)
Curing accelerator A: G-8009L (isocyanate-masked imidazole, manufactured by Daiichi Kogyo Seiyaku Co., Ltd., trade name)

### (Filler)

Silica particles A: SC-2050KC (silica filler treated with phenylaminosilane, average particle size 0.5 μm, manufactured by Admatechs Co., Ltd., trade name)

### <Method for Measuring Hydroxyl Group Equivalent>

In a round-bottom flask, 1 g of a sample was precisely weighed, and 5 mL of an acetic anhydride and pyridine test solution was precisely weighed into the flask. Next, the flask was fitted with an air cooler and heated at 100° C. for 1 hour. After cooling the flask, 1 mL of water was added thereto, and the flask was heated again at 100° C. for 10 minutes. After cooling the flask again, the air cooler and the neck of the flask were rinsed in with 5 mL of neutralized methanol, and 1 mL of a phenolphthalein reagent was added thereto. The solution obtained in this manner was titrated using a 0.1 mol/L potassium hydroxide-ethanol solution, and the hydroxyl group value was determined. From the obtained hydroxyl group value, the hydroxyl group equivalent (g/eq) converted into mass per 1 mol (1 eq) of hydroxyl groups was calculated.

### <Preparation of Conductive Particles>

The following was provided as conductive particles.

### (Conductive Particles 1)

As conductive particles 1, Cu particles (manufactured by Mitsui Mining & Smelting Co., Ltd., trade name “MA-CJU”, average particle size 20 μm, specific gravity 8.9) were provided for use.

(Conductive particles 2)

As conductive particles 2, Cu particles (manufactured by Mitsui Mining & Smelting Co., Ltd., trade name “MA-CKU”, average particle size 10 μm, Specific Gravity 8.9) were Provided for Use.

### <Physical Properties of Conductive Particles>

The amount of change and the amount of restoration when a pressure of 50 mN per particle was applied were measured by a microcompression test using a probe under the following conditions.
Measuring apparatus: “FISCHERSCOPE HM2000” (manufactured by Fischer Instruments K.K.)
Probe size (area): 100 μm×100 μm
Pressing time: Pressing for 50 seconds/returning for 50 seconds
Measurement temperature: 25° C.
Thrust force: 50 mN

The amount of change and the amount of restoration of the conductive particles 1 were 3.39 μm and 0.15 μm, respectively.

The amount of change and the amount of restoration of the conductive particles 2 were 4.86 μm and 0.13 μm, respectively.

### <Production of Member for Wiring Formation>

### Example 1

5.00 g of the epoxy resin A, 4.69 g of the epoxy resin B, 4.08 g of the phenol resin B, 2.68 g of the phenoxy resin A, and 0.025 g of the curing accelerator A were dissolved in 19.1 g of methyl ethyl ketone (MEK), and then 5.36 g of the silica particles A and 4.21 g of the conductive particles 1 were added thereto to prepare a coating liquid for forming an adhesive layer.

This coating liquid was applied on one surface (surface roughness Rz: 3.0 μm) of a copper foil (manufactured by Mitsui Mining & Smelting Co., Ltd., trade name “3EC-M3-VLP”, thickness: 12 μm) using a coating apparatus (manufactured by Yasui Seiki, Inc., product name: Precision Coater) and dried with hot air at 70° C. for 5 minutes to provide an adhesive layer having a thickness of 25 μm on the copper foil. In this way, a member for wiring formation of Example 1 was produced.

### Examples 2 to 11 and Comparative Examples 1 to 3

Members for wiring formation were each produced in the same manner as in Example 1, except that a coating liquid for forming an adhesive layer was prepared with the composition and blending amounts shown in Table 1 or Table 2, and an adhesive layer was formed with the thickness shown in Table 1 or Table 2.

[Thermal Expansion Coefficient when Cured Product of Adhesive Layer is Heated from 40° C. To 260° C.]

The thermal expansion coefficient of a cured product of an adhesive layer was measured by the following procedure.

### [Production of Cured Product]

(1) As a pre-heating evaluation sample, a portion of the adhesive layer is scraped off, and 0.60 g is weighed out.
(2) A silicone sheet having a length of 100 mm, a width of 100 mm, and a thickness of 1 mm is prepared, and a portion of this sheet is gouged out into a piece measuring 5 mm×40 mm×1 mm.
(3) The pre-heating evaluation sample that has been weighed out in (1) is inserted into the gouged-out portion of the silicone sheet.
(4) The silicone sheet with the pre-heating evaluation sample inserted therein is heated and pressurized under the conditions of 180° C. and 2 MPa for 60 minutes using a thermocompression bonding apparatus, to produce a cured product of the pre-heating evaluation sample.

### [Measurement of Thermal Expansion Coefficient of Cured Product]

(1) The cured product of the pre-heating evaluation sample produced as described above is cut out into a piece measuring 5 mm×5 mm×1 mm, and an evaluation sample is produced.
(2) Using a thermomechanical analysis (TMA) apparatus (measurement mode: compression), the amount of change in the thickness when the evaluation sample is heated from 40° C. to 260° C. at a temperature increase rate of 5° C./min is measured, and the thermal expansion coefficient is calculated by the following expression.

$$Thermal expansion coefficient ( \% ) = ( Thickness at 260 ° C . - thickness at 40 ° C . ) \times 100 / ( thickness at 40 ° C . )$$

[Measurement of Reaction Ratio when Heated at 180° C. For 5 Minutes]

For the adhesive layer produced as described above, the reaction ratio when the adhesive layer was heated at 180° C. for 5 minutes was determined by the following method. A portion of the adhesive layer was scraped off, and two 5-mg pre-heating evaluation samples were obtained. Next, one of the pre-heating evaluation samples was heated at 180° C. for 5 minutes to obtain a post-heating evaluation sample. For each of the pre-heating evaluation sample and the post-heating evaluation sample, the DSC calorific value was measured using a differential scanning calorimetry (DSC) apparatus (product name DSC7, manufactured by PERKIN ELMER, Inc.) under a nitrogen gas stream in a measurement temperature range of 30° C. to 250° C. at a temperature increase rate of 10° C./min. Based on the measured DSC calorific value, the reaction ratio when the sample was heated at 180° C. for 5 minutes was determined from the following expression.

$$Reaction ratio = ( C x - C y ) \times 100 / C x$$

wherein Cx represents the DSC calorific value (J/g) of the pre-heating evaluation sample, and Cy represents the DSC calorific value (J/g) of the post-heating evaluation sample.

### [Evaluation of Member for Wiring Formation]

For the member for wiring formation produced as described above, production of an evaluation sample and measurement of the connection resistance value of the evaluation sample were carried out by the following method, and the connection resistance value was evaluated according to the following determination criteria.

### [Measurement of Connection Resistance Value]

### <Production of Evaluation Sample>

The member for wiring formation was stuck to a circuit board (PWB) having three copper circuits with a line width of 1000 μm, a pitch of 10000 μm, and a thickness of 15 μm on a glass cloth-reinforced epoxy substrate. This was heated and pressurized at 180° C. and 2 MPa for 60 minutes using a thermocompression bonding apparatus (heating method: constant heat type, manufactured by Toray Engineering Co., Ltd.) to connect over a width of 2 mm, and a connected body was produced.

A sample obtained by forming a resist on the produced connected body was immersed in an etching solution and subjected to shaking. The etching solution was prepared using copper chloride: 100 g/L, and hydrochloric acid: 100 ml/L. When a predetermined copper foil part was removed, the sample was washed with pure water. Thereafter, the resist was peeled, and a desired evaluation sample was obtained.

### <Evaluation of Evaluation Sample (Initial)>

The resistance value between the copper foil parts remaining on the circuit and the copper circuit on the substrate was measured immediately after adhesion using a multimeter. Regarding the connection resistance value, an average value of the resistance at 37 points between the copper foil parts remaining on the circuit and the copper circuit on the substrate was determined and evaluated according to the following determination criteria.

### [Determination Criteria for Connection Resistance Value]

A: The average value of the resistance value is 5 mΩ or less.
B: The average value of the resistance value is more than 5 mΩ and 10 mΩ or less.
C: The average value of the resistance value is more than 10 mΩ.
   <Evaluation of Evaluation Sample (after Reflow Test)>

The evaluation sample was subjected to a reflow step having the following temperature profile three times, and then the connection resistance value was measured in the same manner as described above and evaluated according to the above-described determination criteria.

Temperature profile: Heated from 50° C. to 150° C. at a temperature increase rate of 2° C./sec, maintained at 150° C. for 100 seconds, subsequently heated from 150° C. to 245° C. at a temperature increase rate of 1° C./sec, maintained at 245° C. for 50 seconds, and then left to cool from 245° C. to 40° C.

### [Mandrel Test]

A mandrel test was performed according to JIS K5600-5-1 on the members for wiring formation produced in Examples and Comparative Examples.

TABLE 1

| | | Example 1 | Example 2 | Example 3 | Example 4 | Example 5 | Example 6 | Example 7 | Example 8 |
|---|---|---|---|---|---|---|---|---|---|
| Thermosetting | Epoxy resin A | 5.00 | 4.38 | 1.23 | 3.46 | 3.38 | 3.46 | — | — |
| component (g) | Epoxy resin B | 4.69 | 4.10 | 5.77 | 5.41 | 5.28 | 5.41 | 7.83 | 8.69 |
| | Epoxy resin C | — | — | 2.81 | 1.32 | 1.29 | 1.32 | 2.04 | 1.32 |
| | Epoxy resin D | — | — | — | — | — | — | — | — |
| | Phenol resin A | — | 3.54 | 4.98 | 4.67 | — | 4.67 | — | — |
| | Phenol resin B | 4.08 | — | — | — | 4.60 | — | 4.87 | 4.73 |
| | Phenol resin C | — | — | — | — | — | — | — | — |
| | Phenoxy resin A | 2.68 | 0.98 | 1.38 | 1.30 | 1.15 | 1.30 | 1.16 | 1.16 |
| | Curing accelerator A | 0.025 | 0.0177 | 0.0249 | 0.0234 | 0.023 | 0.0234 | 0.0233 | 0.0233 |
| | Filler A | 5.36 | 6.83 | 5.29 | 5.29 | 5.18 | 5.29 | 5.25 | 5.25 |
| Conductive | Conductive particles 1 | 4.21 | 4.16 | 4.16 | 4.16 | 4.06 | 4.16 | 4.11 | 4.11 |
| particles (g) | Conductive particles 2 | — | — | — | — | — | — | — | — |
| Thickness of adhesive layer (μm) | | 25 | 25 | 25 | 25 | 21 | 21 | 21 | 21 |
| Content of conductive particles in | | 3.0 | 3.0 | 3.0 | 3.0 | 3.0 | 3.0 | 3.0 | 3.0 |
| adhesive layer (% by volume) | | | | | | | | | |
| Average particle size of conductive | | 20 | 20 | 20 | 20 | 20 | 20 | 20 | 20 |
| particles (μm) | | | | | | | | | |
| Thermal expansion coefficient of cured | | 2.86 | 2.47 | 2.56 | 2.75 | 2.56 | 2.75 | 2.64 | 2.65 |
| product of adhesive layer (%) | | | | | | | | | |
| Reaction ratio of adhesive layer (%) | | 62 | 64 | 64 | 65 | 68 | 66 | 69 | 62 |
| Connection | Initial | A | A | A | A | A | A | A | A |
| resistance value | After reflow test | A | A | A | A | A | A | A | A |

| | | | | | | | | |
|---|---|---|---|---|---|---|---|---|
| Mandrel test (Ø mm) | 2 | 2 | 2 | 2 | 2 | 2 | 2 | 2 |

TABLE 2

| | | | | | Comparative | Comparative | Comparative |
|---|---|---|---|---|---|---|---|
| | | Example 9 | Example 10 | Example 11 | Example 1 | Example 2 | Example 3 |
| Thermosetting | Epoxy resin A | — | — | 3.47 | 5.11 | 5.17 | 3.96 |
| component (g) | Epoxy resin B | 8.66 | 9.45 | 3.26 | 3.72 | 4.85 | 3.71 |
| | Epoxy resin C | 1.32 | 1.44 | — | — | — | — |
| | Epoxy resin D | — | — | — | 0.77 | — | — |
| | Phenol resin A | — | — | 2.81 | 4.59 | 4.18 | — |
| | Phenol resin B | 4.71 | 5.15 | — | — | — | — |
| | Phenol resin C | — | — | — | — | — | 3.26 |
| | Phenoxy resin A | 1.16 | 1.27 | 0.78 | — | — | 2.12 |
| | Curing accelerator A | 0.0232 | 0.0254 | 0.0141 | 0.023 | 0.0209 | 0.0198 |
| | Filler A | 5.23 | 5.71 | 13.56 | 4.69 | 4.69 | 4.24 |
| Conductive | Conductive particles 1 | — | — | 4.16 | 3.68 | 3.68 | 3.33 |
| particles (g) | Conductive particles 2 | 4.1 | 2.2 | — | — | — | — |
| Thickness of adhesive layer (μm) | | 14 | 14 | 25 | 25 | 21 | 21 |
| Content of conductive particles in | | 3.0 | 1.5 | 3.0 | 3.0 | 3.0 | 3.0 |
| adhesive layer (% by volume) | | | | | | | |
| Average particle size of | | 10 | 10 | 20 | 20 | 20 | 20 |
| conductive particles (μm) | | | | | | | |
| Thermal expansion coefficient of cured | | 2.86 | 2.78 | 1.93 | 3.23 | 3.28 | 1.34 |
| product of adhesive layer (%) | | | | | | | |
| Reaction ratio of adhesive layer (%) | | 60 | 62 | 63 | 65 | 66 | 68 |
| Connection | Initial | A | A | A | A | A | A |
| resistance value | After reflow test | A | A | A | C | C | A |

| | | | | | | |
|---|---|---|---|---|---|---|
| Mandrel test (Ø mm) | 2 | 2 | 2 | 2 | 2 | ≥12 |

### REFERENCE SIGNS LIST

1, 1a, 1c, 1e: member for wiring formation, 1d, 1f: wiring layer, 1b: wiring-formed member, 2: member for wiring formation, 10, 10c, 10d, 10A, 10B: adhesive layer, 10a: first surface, 10b: second surface, 10e: first adhesive layer, 10f: second adhesive layer, 12, 12a: conductive particles, 14: adhesive component, 15: first adhesive layer, 16: second adhesive layer, 17: adhesive component, 20: metal layer, 20a: first surface, 20b: second surface, 30: base material, 32: wiring.

1. An adhesive film comprising conductive particles and a thermosetting resin composition,
wherein a cured product of the adhesive film has a thermal expansion coefficient of 1.5% to 3% when heated from 40° C. to 260° C.

2. The adhesive film according to claim 1, wherein the adhesive film has a reaction ratio of 90% or less when heated at 180° C. for 5 minutes.

3. The adhesive film according to claim 1, wherein the conductive particles include copper particles.

4. A metal layer-attached adhesive film comprising:
a metal layer; and
an adhesive layer disposed on the metal layer,
wherein the adhesive layer contains conductive particles and a thermosetting resin composition, and
a cured product of the adhesive layer has a thermal expansion coefficient of 1.5% to 3% when heated from 40° C. to 260° C.

5. The metal layer-attached adhesive film according to claim 4, wherein the adhesive layer has a reaction ratio of 90% or less when heated at 180° C. for 5 minutes.

6. The metal layer-attached adhesive film according to claim 4, wherein the conductive particles include copper particles.

7. The metal layer-attached adhesive film according to claim 4, wherein the metal layer-attached adhesive film is used for forming a wiring.

8. A member for wiring formation comprising an adhesive layer and a metal layer provided as separate entities, the metal layer being adherable to the metal layer at the time of use,
wherein the adhesive layer contains conductive particles and a thermosetting resin composition, and
a cured product of the adhesive layer has a thermal expansion coefficient of 1.5% to 3% when heated from 40° C. to 260° C.

9. The member for wiring formation according to claim 8, wherein the adhesive layer has a reaction ratio of 90% or less when heated at 180° C. for 5 minutes.

10. The member for wiring formation according to claim 8, wherein the conductive particles include copper particles.

11. A method for forming a wiring layer, the method comprising:
providing the metal layer-attached adhesive film according to claim 4;
providing a base material on which a wiring is formed;
disposing the metal layer-attached adhesive film to a surface of the base material on which a wiring is formed so that the metal layer-attached adhesive film covers the wiring, such that the adhesive layer faces the base material;
heating and pressure-bonding the metal layer-attached adhesive film to the base material; and
performing a patterning treatment on the metal layer.

12. A method for forming a wiring layer, the method comprising:
providing the member for wiring formation according to claim 8;
providing a base material on which a wiring is formed;
disposing the member for wiring formation on a surface of the base material on which a wiring is formed so that the member for wiring formation covers the wiring, such that the adhesive layer faces the base material;
heating and pressure-bonding the member for wiring formation to the base material; and
performing a patterning treatment on the metal layer.

13. A wiring-formed member comprising:
a base material having a wiring; and
the cured product of the adhesive layer of the metal layer-attached adhesive film according to claim 4 disposed on the base material to cover the wiring,
wherein the wiring is electrically connected to the metal layer of the metal layer-attached adhesive film or another wiring formed from the metal layer.

14. A wiring-formed member comprising:
a base material having a wiring; and
the cured product of the adhesive layer of the member for wiring formation according to claim 8 disposed on the base material to cover the wiring,
wherein the wiring is electrically connected to the metal layer of the member for wiring formation or another wiring formed from the metal layer.
